(19) United States
(12) Patent Application Publication
(10) Pub. No.: US 2006/0057500 A1
(43) Pub. Date: Mar. 16, 2006

(54) Method of manufacturing lithographic printing plate support

(75) Inventors: Hirokazu Sawada, Shizuoka (JP); Atsuo Nishino, Shizuoka (JP); Akio Uesugi, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/227,167

(22) Filed: Sep. 16, 2005

(30) Foreign Application Priority Data
Sep. 16, 2004 (JP) 2004-269400

(51) Int. Cl. G03F 7/00

(52) U.S. Cl. 430/302

(57) ABSTRACT

Disclosed is a method of manufacturing a lithographic printing plate support including the step of: subjecting an aluminum plate at least to electrochemical graining treatment in which alternating current is passed through the aluminum plate in an aqueous solution containing hydrochloric acid so that the total amount of electricity when the aluminum plate serves as an anode is at least 250 C/dm², thereby obtaining a lithographic printing plate support, wherein the aluminum plate contains not more than 30 ppm of Cu and 10 to 200 ppm of at least one element selected from the group consisting of Ga, V, Zn, In, Ni, Pb and Cr, contains at least 15 ppm of Fe in a form of a solid solution, and has a pattern of recessed and protruded portions formed on a surface thereof. By this method, a lithographic printing plate support which can be used for a presensitized plate excellent in various properties such as press life, scumming resistance and resistance to piling is obtained without performing mechanical graining treatment using nylon brushes and an abrasive.

The entire contents of documents cited in this specification are incorporated herein by reference.

### BACKGROUND OF THE INVENTION

The present invention relates to a method of manufacturing a lithographic printing plate support. More specifically, the invention relates to a method of manufacturing a lithographic printing plate support used for a presensitized plate which has both an excellent scumming resistance and a good press life and which hardly causes piling.

Lithography is a printing process which makes use of a nature that water and oil are essentially unmixable with each other. On the printing surface of a lithographic printing plate used in this process, areas that receive water and repel an oil-based ink (hereinafter referred to as “non-image areas”) and areas that repel water and receive an oil-based ink (hereinafter referred to as “image areas”) are provided.

The surface of an aluminum support for lithographic printing plates used for a lithographic printing plate (hereinafter also referred to simply as “a lithographic printing plate support”) is required to have various conflicting characteristics. For instance, it should be excellent in water wettability and water receptivity because of being so used as to carry non-image areas and at the same time should give good adhesion to the image recording layer formed on it. If the surface of a lithographic printing plate support exhibits too low a water wettability, non-image areas are to be stained with ink upon printing, resulting in generation of dirt on a blanket cylinder or even so-called scumming, that is to say, the scumming resistance is reduced. In addition, if the water receptivity of the surface is too low, certain inconveniences will arise at the time of printing, including plugging of shadows, unless fountain solution is increased in amount. On the other hand, if the adhesion between the support surface and the image recording layer is too poor, the image recording layer is liable to peel off and accordingly the durability (press life) is decreased during printing of a large number of printed sheets.

In fact, the surface of a lithographic printing plate support is subjected to graining treatment and other surface treatments in order to improve various characteristics such as scumming resistance and press life. Examples of a known graining treatment include mechanical graining treatment; electrochemical graining treatment in which alternating current is passed through an aluminum plate immersed in an acidic solution; chemical etching (chemical graining treatment); and a combination thereof.

Among these, mechanical graining treatment plays an effective role for improving the press life. Commonly known for mechanical graining treatment is a method in which a slurry containing an abrasive is sprayed between rotating nylon brushes and an aluminum plate. Mechanical graining treatment using nylon brushes and an abrasive can be performed at high speed and at low cost.

For example, JP 60-36194 A (the term “JP XX-XXXXXX A” as used herein means an “unexamined published Japanese patent application”) describes a lithographic printing plate support made from an aluminum plate on the surface of which elliptical recesses are formed at a density of 200 recesses/mm² or more so as to have an undulating pattern.

JP 60-36195 A describes a lithographic printing plate support which is obtained by forming elliptical recesses on the surface of an aluminum plate at a density of 200 recesses/mm² or more so that the recesses overlap each other to form an undulating pattern, and carrying out electrochemical graining treatment on the plate surface to form fine recesses having an average pitch of 1 to 10 μm.

JP 60-36194 A and JP 60-36195 A describe that a copper roll grained by shot blasting is used to form recesses.

JP 61-162351 A describes a method of manufacturing a lithographic printing plate support by graining in which a roll that has asperities having a center line average roughness (Rₐ) of 0.7 to 1.7 μm, a depth of 6 μm or more and a number of peaks of 500/mm² or more is used to roll an aluminum plate and an aluminum foil to a draft of 2 to 20% by electrical discharge machining.

JP 62-25094 A describes a method of manufacturing a lithographic printing plate support by graining in which a roll that has asperities having a center line average roughness (Rₐ) of 0.5 to 1.5 μm a depth of 6 μm or more and a number of peaks of 500/mm² or more is used to roll an aluminum plate and an aluminum foil to a draft of 2 to 20% by honing or chemical etching.

JP 62-111792 A describes a method of manufacturing a lithographic printing plate support by graining in which a roll that has asperities having a center line average roughness (Rₐ) of 0.5 to 1.5 μm, a depth of 6 μm or more and a number of peaks of 500/mm² or more is used to roll an aluminum plate and an aluminum foil to a draft of 2 to 20% by honing or chemical etching, and electrochemical graining treatment is carried out on the aluminum plate and the aluminum foil to form fine recesses having an average pitch of 1 to 10 μm.

JP 62-11922 B (the term “JP XX-XXXXXX B” as used herein means an “examined Japanese patent publication”) describes a patterning method in which an intermittent energy radiation having an adjustable strength is used to locally destroy a material on the surface of a rolling cylinder for use in improving the properties of a sheet steel thereby patterning thereon.

### SUMMARY OF THE INVENTION

Mechanical graining treatment using nylon brushes and an abrasive causes pointed portions on the surface of an aluminum plate. Therefore, in the case where an image recording layer is formed on the aluminum plate to manufacture a presensitized plate, the thickness of the image recording layer formed on the pointed portions is locally reduced. The image recording layer whose thickness is locally reduced readily wears out compared to the other portions, leading to the reduction of the press life when printing is carried out using a lithographic printing plate obtained therefrom. In order to prevent such a situation, when mechanical graining treatment is carried out using nylon brushes and an abrasive, a large amount of aluminum of the plate is dissolved by the subsequent etching treatment to smooth the pointed portions.

However, the dissolution of a large amount of aluminum of the plate involves considerable cost and also a high load on the environment.

Mechanical graining treatment using nylon brushes and an abrasive has difficulty in controlling the particle size of the abrasive. Therefore, if particles having a larger particle size are incorporated in the abrasive used, locally deep recesses are readily formed on the surface of an aluminum plate. If an image recording layer is formed on the surface of the aluminum plate on which locally deep recesses are formed, the thickness of the image recording layer formed on the recesses is locally increased, thus causing the following problem: When the image recording layer is of a positive type, the image recording layer whose thickness is locally increased is difficult to develop compared to the other portions, and when the image recording layer is of a negative type, an image is not readily formed compared to the other portions.

A method in which alternating current is passed through an aluminum plate in an aqueous solution containing hydrochloric acid is widely used in electrochemical graining treatment because fine asperities can be formed on the surface of the aluminum plate.

The inventors of the present invention have made intensive studies on this method and found that, when a large amount of alternating current electricity is passed through an aluminum plate in an aqueous solution containing hydrochloric acid, a structure of large waves having an average wavelength of about 20 μm and non-uniform recesses having an average diameter of about 0.2 μm are formed so that the latter is superimposed on the former, and hence paper dust or other dust is readily accumulated in the non-uniform recesses (average diameter: about 0.2 μm) formed in the respective recesses of the structure of large waves, which may cause piling. It has also been found that the press life is reduced because of the non-uniform recesses having an average diameter of about 0.2 μm.

The term “piling” as used herein refers to a defect in which, when an accumulation of ink builds up on the blanket cylinder to a certain height during printing, ink in the vicinity of the accumulation is unlikely to be transferred to an image-forming area, whereby no image is formed in that area of a printed sheet.

Therefore, an object of the present invention is to provide a method of manufacturing a lithographic printing plate support with which a presensitized plate excellent in various properties such as press life, scumming resistance and resistance to piling can be obtained without performing mechanical graining treatment using nylon brushes and an abrasive.

The inventors of the present invention have made intensive studies to achieve the above object and as a result found that, when an aluminum plate in which the Cu content, the contents of specific alloy components and the amount of Fe in solid solution are within specified ranges is subjected to electrochemical graining treatment in which alternating current is passed through the aluminum plate in an aqueous solution containing hydrochloric acid so that the amount of electricity when the aluminum plate serves as an anode can be 250 C/dm², thereby obtaining a lithographic printing plate support, a presensitized plate using the thus obtained support is excellent in both of scumming resistance and press life and has also high resistance to piling.

According to the present invention, there are provided the following (1) to (6).

(1) A method of manufacturing a lithographic printing plate support including the step of:
subjecting an aluminum plate at least to electrochemical graining treatment in which alternating current is passed through the aluminum plate in an aqueous solution containing hydrochloric acid so that the total amount of electricity when the aluminum plate serves as an anode is at least 250 C/dm², thereby obtaining a lithographic printing plate support,
wherein the aluminum plate contains not more than 30 ppm of Cu and 10 to 200 ppm of at least one element selected from the group consisting of Ga, V, Zn, In, Ni, Pb and Cr, contains at least 15 ppm of Fe in a form of a solid solution, and has a pattern of recessed and protruded portions formed on a surface thereof.

(2) The method of manufacturing a lithographic printing plate support according to (1), in which the aluminum plate contains 0.05 to 0.4 wt % of Fe.

(3) The method of manufacturing a lithographic printing plate support according to (1) or (2), in which the aluminum plate is etched using an alkaline aqueous solution prior to the electrochemical graining treatment so that the amount of aluminum dissolved is not more than 7 g/m².

(4) The method of manufacturing a lithographic printing plate support according to any one of (1) to (3), in which the pattern of recessed and protruded portions on the surface of the aluminum plate is formed by rolling using a roll having a pattern of recessed and protruded portions formed on a surface thereof.

(5) The method of manufacturing a lithographic printing plate support according to any one of (1) to (4), in which the aluminum plate satisfies one or more selected from the group consisting of a Si content of 0.03 to 0.1 wt %, a Ti content of 0.001 to 0.03 wt % and a Mg content of 0.001 to 0.5 wt %.

(6) The method of manufacturing a lithographic printing plate support according to any one of (1) to (5), in which the aqueous solution containing hydrochloric acid further contains nitric acid or sulfuric acid.

As will be described later, the present invention can provide a lithographic printing plate support used for a presensitized plate which has excellent scumming resistance and a long press life and is highly resistant to piling when made into a lithographic printing plate.

### BRIEF DESCRIPTION OF THE DRAWINGS

In the accompanying drawings:

FIG. 1 is a schematic cross-sectional view of an apparatus for rinsing with a free-falling curtain of water that is used for rinsing in the method of manufacturing a lithographic printing plate support according to the present invention;

FIG. 2 is a graph showing an example of an alternating current waveform that is used in electrochemical graining treatment in the method of manufacturing a lithographic printing plate support according to the present invention;

FIG. 3 is a side view of a radial electrolytic cell that is used to carry out electrochemical graining treatment with alternating current in the method of manufacturing a lithographic printing plate support according to the present invention; and

FIG. 4 is a schematic view of an anodizing apparatus that is used in anodizing treatment in the method of manufacturing a lithographic printing plate support according to the present invention.

### DETAILED DESCRIPTION OF THE INVENTION

The present invention will be described below in detail.

[Method of Manufacturing Lithographic Printing Plate Support]

<Aluminum Plate (Rolled Aluminum)>

In an aluminum plate used in the method of manufacturing a lithographic printing plate support of the present invention (hereinafter also referred to simply as an “aluminum plate”), the Cu content is not more than 30 ppm and preferably not more than 15 ppm; the content of at least one element selected from the group consisting of Ga, V, Zn, In, Ni, Pb and Cr is 10 to 200 ppm, preferably 30 to 200 ppm and more preferably 50 to 200 ppm; and the amount of Fe in solid solution is at least 15 ppm, preferably at least 20 ppm and more preferably at least 30 ppm.

In general, when a large amount of electricity is used to carry out electrochemical graining treatment in an aqueous solution containing hydrochloric acid on an aluminum plate containing a considerably large amount of Cu, a structure of large waves having an average wavelength of about 20 μm and non-uniform recesses having an average diameter of 0.2 μm are formed in a superimposed manner.

On the other hand, the aluminum plate used in the method of manufacturing a lithographic printing plate support of the present invention contains not more than 30 ppm of Cu, and hence the aluminum plate having undergone electrochemical graining treatment to be described later has a surface profile in which there are no coarse pits and uniform pits having an average diameter of 0.1 to 0.5 μm are superimposed on uniform recesses (pits) having an average diameter of 2 to 10 μm.

The Cu content in the aluminum plate can be made to fall within the above ranges by selecting a starting material containing a small amount of Cu and dispensing with the addition of Cu during the manufacture of the aluminum plate.

Since the content of at least one element selected from the group consisting of Ga, V, Zn, In, Ni, Pb and Cr is 10 ppm or more, uniformity of the recesses formed on the surface of the aluminum plate by electrochemical graining treatment to be described later is enhanced. Since the content is also 200 ppm or less, costs required for the manufacture can de reduced.

Since the amount of Fe retained in the solid solution of the aluminum plate is at least 15 ppm, a presensitized plate using a lithographic printing plate support manufactured by the manufacturing method of the present invention has a satisfactory mechanical strength (tensile strength, 0.2% proof strength) and has improved resistance to softening due to heating treatment (burning) after exposure or deformation that may occur when development making use of heat is performed.

The amount of Fe contained in the aluminum plate is preferably 0.05 to 0.4 wt %, more preferably 0.15 to 0.37 wt % and even more preferably 0.2 to 0.35 wt % such that the amount of Fe retained in the solid solution of the aluminum plate can be at least 15 ppm.

The aluminum plate preferably contains at least one element selected from the group consisting of 0.03 to 0.1 wt % of Si, 0.001 to 0.03 wt % of Ti and 0.001 to 0.5 wt % of Mg.

If the aluminum plate contains 0.03 to 0.1 wt % of Si, the respective pits formed have independent shapes and the surface profile obtained by electrochemical graining is stabilized. If the aluminum plate contains 0.001 to 0.03 wt % of Ti, the crystal structure is made finer in the casting to be described later. If the aluminum plate contains 0.001 to 0.05 wt % of Mg, resistance to softening of a presensitized plate that may be caused during burning by dissolving Fe in a solid solution can be further enhanced.

The aluminum plate may further contain elements other than Cu, Fe, Ga, V, Zn, In, Ni and Pb. The aluminum plate contains these other elements according to JXS A1050, JIS A1100, JIS A1070 or the like described in the 4^{th} edition of Aluminum Handbook published in 1990 by the Light Metal Association (Japan).

The aluminum alloy may be rendered into plate by the following method, for example. An aluminum alloy melt that has been adjusted to a given alloying ingredient content is initially subjected to cleaning treatment by an ordinary method, and then is cast. Cleaning treatment, which is carried out to remove hydrogen and other unnecessary gases from the melt, typically involves flux treatment; degassing treatment using argon gas, chlorine gas or the like; filtering treatment using, for example, what is referred to as a rigid media filter (e.g., ceramic tube filters, ceramic foam filters), a filter that employs a filter medium such as alumina flakes or alumina balls, or a glass cloth filter; or a combination of degassing treatment and filtering treatment.

Cleaning treatment is preferably carried out to prevent defects due to foreign matter such as nonmetallic inclusions and oxides in the melt, and defects due to dissolved gases in the melt. The filtration of melts is described in, for example, JP 6-57432 A, JP 3-162530 A, JP 5-140659 A, JP 4-231425 A, JP 4-276031 A, JP 5-311261 A, and JP 6-136466 A. The degassing of melts is described in, for example, JP 5-51659 A and JP 5-49148 U (the term “JP XX-XXXXXX U” as used herein means an “unexamined published Japanese utility model application”). The present applicant discloses related art concerning the degassing of melts in JP 7-40017 A.

Next, the melt that has been subjected to cleaning treatment as described above is cast. Casting processes include those which use a stationary mold, such as direct chill casting, and those which use a moving mold, such as continuous casting.

In direct chill casting, the melt is solidified at a cooling speed of 0.5 to 30° C. per second. At less than 0.5° C./sec, many coarse intermetallic compounds may be formed. When direct chill casting is carried out, an ingot having a thickness of 300 to 800 mm can be obtained. If necessary, this ingot is scalped by a conventional method, generally removing 1 to 30 mm, and preferably 1 to 10 mm, of material from the surface.

The ingot may also be optionally soaked, either before or after scalping. In the case where soaking is carried out, the ingot is heat treated at 400 to 620° C. and preferably 450 to 620° C. for 1 to 48 hours. When the soaking temperature is 400 to 620° C., intermetallic compounds are not coarsened, and when the soaking temperature is 450 to 620° C., the amount of Fe retained in the solid solution of the aluminum plate is increased. The effects of soaking treatment may be inadequate if heat treatment is shorter than one hour. If soaking treatment is not carried out, this can have the advantage of lowering costs.

The ingot is then hot-rolled and cold-rolled, giving a rolled aluminum plate. A temperature of 350 to 500° C. at the start of hot rolling is appropriate. Intermediate annealing may be carried out before or after hot rolling, or even during hot rolling.

The intermediate annealing conditions consist of 2 to 20 hours of heating at 280 to 600° C., and preferably 2 to 10 hours of heating at 350 to 500° C., in a batch-type annealing furnace, or of heating for up to 6 minutes at 400 to 600° C., and preferably up to 2 minutes at 450 to 550° C., in a continuous annealing furnace. Using a continuous annealing furnace to heat the rolled plate at a temperature rise rate of 10 to 200° C./sec enables a finer crystal structure to be achieved.

When using a batch-type annealing furnace, the heating temperature is preferably at least 400° C. and more preferably at least 450° C. At a heating temperature of at least 400° C., intermediate annealing can be performed without precipitating out Fe dissolved in the aluminum matrix.

When using a continuous annealing furnace, a lower heating temperature may be used, because the heating time is short and precipitation does not readily take place.

Continuous casting processes that are industrially carried out include processes which use cooling rolls, such as the twin roll process (Hunter process) and the 3C process, the twin belt process (Hazelett process), and processes which use a cooling belt or a cooling block, such as the Alusuisse Caster II process. When a continuous casting process is used, the melt is solidified at a cooling rate of 100 to 1,000° C./sec. Continuous casting processes generally have a faster cooling rate than direct chill casting processes, and so are characterized by the ability to achieve a higher solid solubility of alloying ingredients in the aluminum matrix. Technology relating to continuous casting processes that has been disclosed by the present applicant is described in, for example, JP 3-79798 A, JP 5-201166 A, JP 5-156414 A, JP 6-262203 A, JP 6-122949 A, JP 6-210406 A and JP 6-26308 A.

When continuous casting is carried out, such as by a process involving the use of cooling rolls (e.g., the Hunter process), the melt can be directly and continuously cast as a plate having a thickness of 1 to 10 mm, thus making it possible to omit the hot rolling step. Moreover, when use is made of a process that employs cooling belts (e.g., the Hazelett process), a plate having a thickness of 10 to 50 mm can be cast. Generally, by positioning a hot-rolling roll immediately downstream of the caster, the cast plate can then be successively rolled, enabling a continuously cast and rolled plate with a thickness of 1 to 10 mm to be obtained.

These continuously cast and rolled plates are then subjected to such processes as cold rolling, intermediate annealing, flattening and slitting in the same way as described above for direct chill casting, and thereby finished to a plate thickness of 0.1 to 0.5 mm, for instance. Technology disclosed by the present applicant concerning the intermediate annealing conditions and cold rolling conditions in a continuous casting process is described in, for example, JP 6-220593 A, JP 6-210308 A, JP 7-54111 A and JP 8-92709 A.

A pattern of recessed and protruded portions are formed on the aluminum plate used in the present invention in the final rolling process or the like by press rolling, transfer or another method.

In particular, it is preferable to employ a method in which a surface with a pattern of recessed and protruded portions is pressed onto the surface of the aluminum plate to transfer the pattern thereto and provide thereby the pattern of recessed and protruded portions thereon during the cold rolling for adjusting the final plate thickness or finish cold rolling for finishing the surface profile after the adjustment of the final plate thickness. More specifically, the method described in JP 6-262203 A can be advantageously used.

The pattern of recessed and protruded portions transferred to the surface of the aluminum plate by this method has more gentle slopes than that transferred to the surface of the aluminum plate by mechanical graining treatment using nylon brushes and an abrasive.

By using the aluminum plate having the pattern of recessed and protruded portions transferred to its surface, it is possible to reduce energy consumption in subsequent alkali etching treatment and graining treatment and to facilitate control of the amount of fountain solution on a printing press. More specifically, the amount of material removed by etching (also referred to below as “etching amount”) in a first etching treatment to be described later can be reduced to about 7 g/m² or less.

It is particularly preferable to carry out such transfer as above concurrently with the commonly performed final cold rolling. The aluminum plate is preferably rolled for transfer in the last pass.

Examples of the method of obtaining a roll for metal rolling which has a pattern of recessed and protruded portions provided on its surface and is used for the transfer of the recessed and protruded portions (roll being hereinafter also referred to as “transfer roll”) are described in JP 60-36195 A, JP 2002-251005 A, JP 60-203495 A, JP 55-74898 A and JP 62-111792 A.

Other examples of the method of obtaining a transfer roll include blasting method, electrolytic method, laser method, electrical discharge machining method and a combination thereof. Among these, a combination of blasting method and electrolytic method is preferable. Air blasting method is preferred to other blasting methods.

There is no particular limitation on the grit used in the air blasting method as long as alumina particles of a predetermined particle size are used. When hard alumina particles each having sharp edges are used as the grit, deep and uniform recessed and protruded portions can easily be provided on the surface of the transfer roll.

The surface of the transfer roll has preferably an average surface roughness (Rₐ) of 0.4 to 1.0 μm and more preferably 0.6 to 0.9 μm.

The number of peaks of the transfer roll surface is preferably 1,000 to 40,000/mm² and more preferably 2,000 to 10,000/mm². If the number of peaks is too small, the water receptivity of the lithographic printing plate support and its adhesion to the image recording layer are impaired. An impaired water-receptivity may cause scumming in halftone dot areas of the lithographic printing plate prepared using the support.

There is no particular limitation on the material for the transfer roll and any known material for rolls for metal rolling can be used for example.

It is particularly preferable to use a roll fabricated by casting. In this case, the roll has preferably a hardness (Hs) of 80 to 100 after quenching and tempering are carried out. The tempering is preferably carried out at a low temperature.

The transfer roll having a pattern of recessed and protruded portions provided thereon by the air blasting method or the like is preferably subjected to a hardening treatment, such as quenching or hard chromium plating, after cleaning, which improves the wear resistance and service life of the roll.

Preferably, electrolytic treatment is performed on the transfer roll before hard chromium plating by passing direct current through the roll as an anode in the same plating solution as to be used for hard chromium plating at an amount of electricity of 5,000 to 50,000 C/dm². The treatment enables the surface of the roll to have uniform recessed and protruded portions.

The aluminum plate manufactured as described above may then be flattened with a leveling machine such as a roller leveler or a tension leveler. The plate may also be passed through a slitter line to cut it to a predetermined width. A thin film of oil may be provided on the aluminum plate to prevent scuffing due to rubbing between adjoining aluminum plates. Suitable use may be made of either a volatile or non-volatile oil film, as needed.

It is desirable for the aluminum plate manufactured as described above to have the following properties.

For the aluminum plate to achieve the stiffness required of a lithographic printing plate support, it should have a 0.2% proof strength of preferably at least 120 MPa. To ensure some degree of stiffness even when burning treatment has been carried out, the 0.2% proof strength following 3 to 10 minutes of heat treatment at 270° C. should be preferably at least 80 MPa, and more preferably at least 100 MPa. The aluminum plate can have the stiffness by adjusting the amount of Fe in solid solution to at least 15 ppm.

The aluminum plate more preferably has a tensile strength of 160±15 N/mm², a 0.2% proof strength of 140±15 MPa, and an elongation as defined in JIS Z2241 and Z2201 of 1 to 10%.

Because the crystal structure at the surface of the aluminum plate may give rise to a poor surface quality when chemical graining treatment or electrochemical graining treatment is carried out, it is preferable that the crystal structure not be too coarse. The crystal structure at the surface of the aluminum plate has a width of preferably up to 200 μm, more preferably up to 100 μm, and most preferably up to 50 μm. Moreover, the crystal structure has a length of preferably up to 5,000 μm, more preferably up to 1,000 μm, and most preferably up to 500 μm. Related technology disclosed by the present applicant is described in, for example, JP 6-218495 A, JP 7-39906 A and JP 7-124609 A.

The aluminum plate is well-tempered in accordance with H18 defined in JIS.

The aluminum plate preferably has a thickness of about 0.1 to 0.6 mm, more preferably 0.15 to 0.4 mm, and even more preferably 0.2 to 0.3 mm. This thickness can be changed as appropriate based on such considerations as the size of the printing press, the size of the printing plate and the desires of the user.

The average roughness Rₐ of the aluminum plate is preferably 0.3 to 0.9 μm and more preferably 0.4 to 0.8 μm.

The average roughness Rₐ is measured as follows: Two-dimensional roughness measurement is conducted using a stylus-type roughness tester (e.g., Surfcom 575 manufactured by Tokyo Seimitsu Co., Ltd.). The average roughness Rₐ as defined by ISO 4287 is measured five times, and the mean of the five measurements is used as the value of the average roughness.

The conditions of the two-dimensional roughness measurement are described below.

<Measurement Conditions>

Cutoff value, 0.8 mm; slope correction, FLAT-ML; measurement length, 3 mm; vertical magnification, 10,000×; scan rate, 0.3 mm/sec; stylus tip diameter, 2 μm.

The aluminum plate used in this invention is in the form of a continuous sheet or discrete sheets. That is, it may be either an aluminum web or a cut sheet of aluminum having a size which corresponds to the presensitized plates that will be shipped as the final products.

Because scratches and other marks on the surface of the aluminum plate may become defects when the plate is fabricated into a lithographic printing plate support, it is essential to minimize the formation of such marks prior to the surface treatment operations for rendering the aluminum plate into a lithographic printing plate support. It is thus desirable for the aluminum plate to be stably packed in such a way that it will not be easily damaged during transport.

When the aluminum plate is in the form of a web, it may be packed by, for example, laying hardboard and felt on an iron pallet, placing corrugated cardboard doughnuts on either side of the product, wrapping everything with polytubing, inserting a wooden doughnut into the opening at the center of the coil, stuffing felt around the periphery of the coil, tightening steel strapping about the entire package, and labeling the exterior. In addition, polyethylene film can be used as the outer wrapping material, and needled felt and hardboard can be used as the cushioning material. Various other forms of packing exist, any of which may be used so long as the aluminum plate can be stably transported without being scratched or otherwise marked.

<Surface Treatment>

In the method of manufacturing a lithographic printing plate support according to the present invention, the aluminum plate as described above is subjected to electrochemical graining treatment in which alternating current is passed through the aluminum plate in an aqueous solution containing hydrochloric acid so that the total amount of electricity when the aluminum plate serves as an anode is at least 250 C/dm², thereby obtaining a lithographic printing plate support.

In the method of manufacturing a lithographic printing plate support according to the present invention, various processes other than electrochemical graining treatment may be included.

A specific example of a suitable surface treatment method includes a method in which etching treatment in an aqueous alkali solution (hereinafter referred to as “first etching treatment”), desmutting treatment in an aqueous acidic solution (hereinafter referred to as “first desmutting treatment”), electrochemical graining treatment, etching treatment in an aqueous alkali solution (hereinafter referred to as “second etching treatment”), desmutting treatment in an aqueous acidic solution (hereinafter referred to as “second desmutting treatment”), and anodizing treatment are carried out in this order.

Another method in which sealing treatment, hydrophilizing treatment, or sealing treatment followed by hydrophilizing treatment is carried out after the anodizing treatment is also preferable. The respective surface treatment processes will be described below in detail.

<First Etching Treatment>

Alkali etching treatment is a treatment in which the surface layer of the above-described aluminum plate is dissolved by bringing the aluminum plate into contact with an alkali solution.

The purpose of the first etching treatment carried out prior to electrochemical graining treatment is to enable the formation of uniform recesses in the electrochemical graining treatment and to remove substances such as rolling oil, contaminants and a natural oxide film from the surface of the aluminum plate (rolled aluminum).

The amount of material removed in the first etching treatment from the surface to be subsequently subjected to electrochemical graining treatment is preferably not more than 7 g/m², more preferably not more than 5 g/m² and even more preferably not more than 4 g/m² but preferably at least 0.1 g/m², more preferably at least 0.5 g/m² and even more preferably 1 g/m².

In an etching amount of not more than 7 g/m², dissolution of Cu contained in the aluminum plate in an alkali solution is decreased. Therefore, precipitation of Cu having been dissolved in the alkali solution on the surface of the aluminum plate can be suppressed and uniform pits can be formed by electrochemical graining treatment. The amount of alkali solution used is also decreased, which is economically advantageous. In an etching amount of 0.1 g/m² or more, substances such as rolling oil, contaminants and a natural oxide film can be sufficiently removed from the surface of the aluminum plate.

Alkalis that may be used in the alkali solution are exemplified by caustic alkalis and alkali metal salts. Specific examples of suitable caustic alkalis include sodium hydroxide and potassium hydroxide. Specific examples of suitable alkali metal salts include alkali metal silicates such as sodium metasilicate, sodium silicate, potassium metasilicate and potassium silicate; alkali metal carbonates such as sodium carbonate and potassium carbonate; alkali metal aluminates such as sodium aluminate and potassium aluminate; alkali metal aldonates such as sodium gluconate and potassium gluconate; and alkali metal hydrogenphosphates such as dibasic sodium phosphate, dibasic potassium phosphate, tribasic sodium phosphate and tribasic potassium phosphate. Among others, caustic alkali solutions and solutions containing both a caustic alkali and an alkali metal aluminate are preferred on account of the high etch rate and low cost. An aqueous solution of sodium hydroxide is especially preferred.

In the first etching treatment, the alkali solution has a concentration of preferably at least 30 g/L, and more preferably at least 300 g/L, but preferably not more than 500 g/L, and more preferably not more than 450 g/L.

It is desirable for the alkali solution to contain aluminum ions. The aluminum ion concentration is preferably at least 1 g/L, and more preferably at least 50 g/L, but preferably not more than 200 g/L, and more preferably not more than 150 g/L. Such an alkali solution can be prepared from, for example, water, a 48 wt % solution of sodium hydroxide in water, and sodium aluminate.

In the first etching treatment, the alkali solution temperature is preferably at least 30° C., and more preferably at least 50° C., but preferably not more than 80° C., and more preferably not more than 75° C.

The treatment time in the first etching treatment is preferably at least 1 second, and more preferably at least 2 seconds, but preferably not more than 30 seconds, and more preferably not more than 15 seconds.

When the aluminum plate is continuously etched, the aluminum ion concentration in the alkali solution rises and the etching amount at which the aluminum plate is treated changes. It is thus preferable to control the etching solution composition as follows.

First, a matrix of the electrical conductivity, specific gravity and temperature or a matrix of the conductivity, ultrasonic wave propagation velocity and temperature is prepared with respect to a matrix of the sodium hydroxide concentration and the aluminum ion concentration. The solution composition is then determined based on either the conductivity, specific gravity and temperature or the conductivity, ultrasonic wave propagation velocity and temperature, and sodium hydroxide and water are added up to control target values for the solution composition. Next, the etching solution which has increased in volume with the addition of sodium hydroxide and water is allowed to overflow from a circulation tank, thereby keeping the amount of solution constant. The sodium hydroxide added may be industrial grade 40 to 60 wt % sodium hydroxide.

The conductivity meter and hydrometer used to measure electrical conductivity and specific gravity, respectively, are preferably temperature-compensated instruments. The hydrometer is preferably a pressure differential hydrometer.

Illustrative examples of methods for bringing the aluminum plate into contact with the alkali solution include a method in which the aluminum plate is passed through a tank filled with an alkali solution, a method in which the aluminum plate is immersed in an alkali solution contained in a tank, and a method in which the surface of the aluminum plate is sprayed with an alkali solution.

The most desirable of these is a method that involves spraying the surface of the aluminum plate with an alkali solution. Specifically, in such a method, the etching solution is sprayed onto the aluminum plate from a spray line, which bears 2 to 5 mm diameter openings at a pitch of 10 to 50 mm, at a rate of 10 to 100 L/min per spray line. It is preferred that two or more spray lines be employed.

Following the completion of alkali etching treatment, it is desirable to remove the etching solution from the aluminum plate with nip rollers, subject the plate to rinsing treatment with water for 1 to 10 seconds, then remove the water with nip rollers.

Rinsing treatment is preferably carried out by rinsing with a rinsing apparatus that uses a free-falling curtain of water and then rinsing further with a spray line.

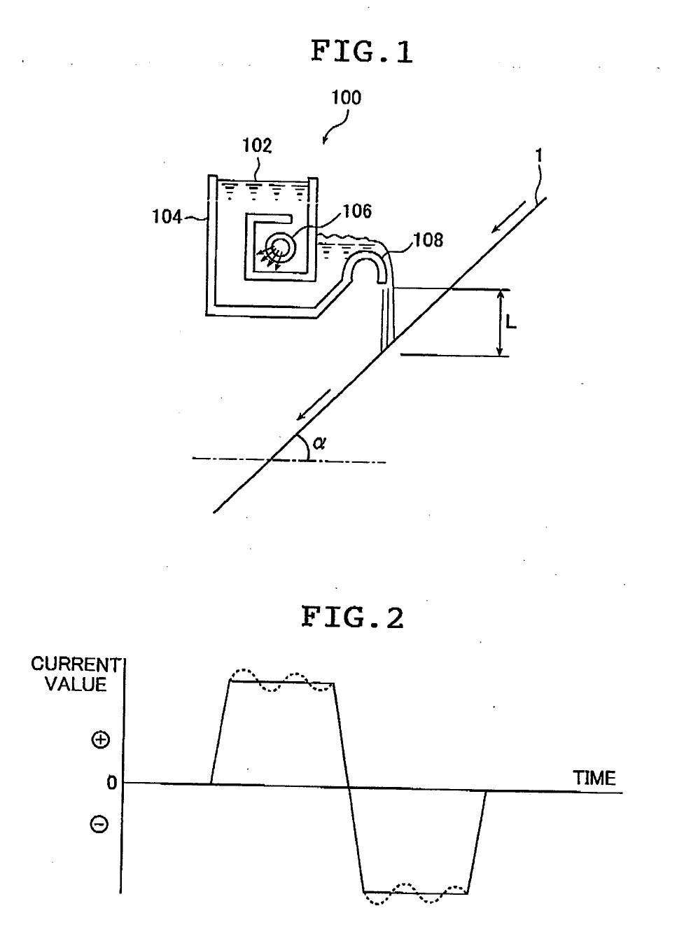

FIG. 1 is a schematic cross-sectional view of an apparatus 100 for carrying out rinsing treatment with a free-falling curtain of water. As shown in FIG. 1, the apparatus 100 that carries out rinsing with a free-falling curtain of water has a water holding tank 104 that holds water 102, a pipe 106 that feeds water to the water holding tank 104, and a flow distributor 108 that supplies a free-falling curtain of water from the water holding tank 104 to an aluminum plate 1.

In this apparatus 100, the pipe 106 feeds water 102 to the water holding tank 104. When the water 102 overflows the water holding tank 104, it is distributed by the flow distributor 108 and the free-falling curtain of water is supplied to the aluminum plate 1. A flow rate of 10 to 100 L/min is preferred when this apparatus 100 is used. The distance L between the apparatus 100 and the aluminum plate 1 over which the water 102 exists as a free-falling liquid curtain is preferably from 20 to 50 mm. Moreover, it is preferable for the aluminum plate to be inclined at an angle α to the horizontal of 30 to 80°.

By using an apparatus like that in FIG. 1 which rinses the aluminum plate with a free-falling curtain of water, the aluminum plate can be uniformly rinsed. This in turn makes it possible to enhance the uniformity of treatment carried out prior to rinsing.

A preferred example of an apparatus that carries out rinsing treatment with a free-falling curtain of water is described in JP 2003-96584 A.

Rinsing with a spray line may be carried out by the use of, for instance, a spray line having a plurality of spray tips disposed along the width of the aluminum plate, each of which discharges a fanned-out spray of water. The interval between spray tips is preferably 20 to 100 mm, and the amount of water discharged per spray tip is preferably 0.5 to 20 L/min. The use of a plurality of spray lines is preferred.

<First Desmutting Treatment>

After the first etching treatment, it is preferable to carry out acid pickling (first desmutting treatment) to remove contaminants (smut) remaining on the surface of the aluminum plate. Desmutting treatment is carried out by bringing the aluminum plate into contact with an acidic solution. Examples of acids that may be used include nitric acid and sulfuric acid. For instance, an aqueous solution of sulfuric acid as the wastewater from the anodizing treatment to be described later can suitably be used.

The composition of the desmutting treatment solution may be controlled based on the electrical conductivity and temperature, or on the electrical conductivity, specific gravity and temperature, or on the electrical conductivity, ultrasonic wave propagation velocity and temperature, which parameters are corresponding to a matrix of the acidic solution concentration and the aluminum ion concentration.

In the first desmutting treatment, it is preferable to use an acidic solution containing 1 to 400 g/L of an acid and 0.1 to 5 g/L of aluminum ions.

The temperature of the acidic solution is preferably at least 20° C. and more preferably at least 30° C. but preferably not more than 70° C. and more preferably not more than 60° C.

Illustrative examples of the method of bringing the aluminum plate into contact with the acidic solution include passing the aluminum plate through a tank filled with the acidic solution, immersing the aluminum plate in the acidic solution contained in a tank, and spraying the acidic solution onto the surface of the aluminum plate.

Of these, a method in which the acidic solution is sprayed onto the surface of the aluminum plate is preferred. Specifically, in such a method, the desmutting treatment solution is sprayed onto the aluminum plate from a spray line bearing 2 to 5 mm diameter openings at a pitch of 10 to 50 mm at a rate of 10 to 100 L/min per spray line. It is preferable that two or more spray lines be employed.

After desmutting treatment, it is preferable to remove the solution with nip rollers, then carry out rinsing treatment with water for 1 to 10 seconds and again remove the water with nip rollers.

<Electrochemical Graining Treatment>

Electrochemical graining treatment is a treatment in which alternating current is passed through the aluminum plate in an aqueous solution containing hydrochloric acid so that the total amount of electricity when the aluminum plate serves as an anode is at least 250 C/dm².

This electrochemical graining treatment allows an aluminum plate having a surface profile in which uniform pits having an average diameter of 0.1 to 0.5 μm are superimposed on uniform recesses (pits) having an average diameter of 2 to 10 μm to be obtained.

According to the present invention, pits are formed uniformly on the surface of the aluminum plate after electrochemical graining treatment and the surface area is increased. Therefore, the press life of a lithographic printing plate prepared is enhanced. Moreover, uniform pits result in an excellent scumming resistance of the lithographic printing plate.

Since coarse pits are not formed on the surface of the aluminum plate after electrochemical graining treatment, gentle slopes in the pattern of recessed and protruded portions formed by the rolling step or the like are not impaired. Therefore, piling hardly occurs on the lithographic printing plate prepared because paper dust is unlikely to be accumulated in the non-image areas.

Piling is likely to occur on a lithographic printing plate of a printing system such as FM (frequency modulation) screening which uses fine halftone dots in the image areas, whereas piling is unlikely to occur on a lithographic printing plate obtained using the lithographic printing plate support manufactured by the manufacturing method of the present invention even if the above printing system is adopted.

Since coarse pits are not formed on the surface of the aluminum plate after electrochemical graining treatment, the image recording layer of the lithographic printing plate prepared is highly uniform in thickness as will be described later. Therefore, development can be carried out uniformly. The press life can be prevented from being reduced due to the wear-out of thin portions of the image recording layer.

When the total amount of electricity when the aluminum plate serves as an anode is at least 250 C/dm², electrochemical graining treatment is sufficiently carried out on the aluminum plate to form asperities having such a surface profile that the pits having an average diameter of 0.1 to 0.5 μm are uniformly superimposed on the pits having an average diameter of 2 to 10 μm.

The total amount of electricity when the aluminum plate serves as an anode is preferably not more than 600 C/dm². The total amount of electricity of not more than 600 C/dm² is economically advantageous.

The current density is preferably 10 to 100 A/dM² as a peak current value.

The hydrochloric acid concentration in the aqueous solution to be used for the electrolyte solution can be adjusted by adding at least one of chloride compounds containing chloride ions such as aluminum chloride, sodium chloride and ammonium chloride to 1 to 100 g/L aqueous hydrochloric acid solution in the range of 1 g/L to saturation amount. If the amount of the chloride compound added is within the above range, the uniformity of pits is enhanced.

A metal contained in an aluminum alloy such as iron, copper, manganese, nickel, titanium, magnesium or silica may be dissolved in the aqueous solution containing hydrochloric acid.

More specifically, a solution having 3 to 7 g/L of aluminum ions is preferably prepared by dissolving aluminum chloride in an aqueous solution having a hydrochloric acid concentration of 2 to 10 g/L.

The temperature of the aqueous solution containing hydrochloric acid is preferably at least 25° C. and more preferably at least 30° C., but preferably not more than 55° C. and more preferably not more than 40° C.

When the aluminum plate is continuously electrolyzed, the aluminum ion concentration in the aqueous solution containing hydrochloric acid rises and the shapes of the asperities formed on the plate surface change. It is thus preferable to control the hydrochloric acid electrolyte solution composition as follows.

First, a matrix of the electrical conductivity, specific gravity and temperature or a matrix of the conductivity, ultrasonic wave propagation velocity and temperature is prepared with respect to a matrix of the hydrochloric acid concentration and the aluminum ion concentration. The solution composition is then determined based on either the conductivity, specific gravity and temperature or the conductivity, ultrasonic wave propagation velocity and temperature, and hydrochloric acid and water are added up to control target values for the solution composition. Next, the electrolyte solution which has increased in volume with the addition of hydrochloric acid and water is allowed to overflow a circulation tank, thereby keeping the amount of solution constant. The hydrochloric acid added may be industrial grade 10 to 40 wt % hydrochloric acid.

The conductivity meter and hydrometer used to measure electrical conductivity and specific gravity, respectively, are preferably temperature-compensated instruments. The hydrometer is preferably a pressure differential hydrometer.

For the measurement accuracy, the sample collected from the electrolyte solution for the composition measurement is preferably used for the measurement after having been controlled so as to be maintained at a predetermined temperature (e.g., 35±0.5° C.) using a different heat exchanger from that used for the electrolyte solution.

Electrochemical graining treatment may be carried out in accordance with, for example, the electrochemical graining processes (electrolytic graining processes) described in JP 48-28123 B and GB 896,563.

Various electrolytic cells and power supplies have been proposed for use in electrolytic treatment. For example, use may be made of those described in U.S. Pat. No. 4,203,637, JP-56-123400 A, JP 57-59770 A, JP 53-12738 A, JP 53-32821 A, JP 53-32822 A, JP 53-32823 A, JP 55-122896 A, JP 55-132884 A, JP 62-127500 A, JP 1-52100 A, JP 1-52098 A, JP 60-67700 A, JP 1-230800 A, JP 3-257199 A, JP 52-58602 A, JP 52-152302 A, JP 53-12738 A, JP 53-12739 A, JP 53-32821 A, JP 53-32822 A, JP 53-32833 A, JP 53-32824 A, JP 53-32825 A, JP 54-85802 A, JP 55-122896 A, JP 55-132884 A, JP 48-28123 B, JP 51-7081 B, JP 52-133838 A, JP 52-133840 A, JP 52-133844 A, JP 52-133845 A, JP 53-149135 A and JP 54-146234 A.

By adding and using a compound capable of forming a complex with copper, uniform graining may be carried out even on an aluminum plate having a high copper content. Examples of the compound capable of forming a complex with copper include ammonia; amines obtained by substituting the hydrogen atom on ammonia with a hydrocarbon group (of an aliphatic, aromatic, or other nature), such as methylamine, ethylamine, dimethylamine, diethylamine, trimethylamine, cyclohexylamine, triethanolamine, triisopropanolamine and ethylenediamine tetraacetate (EDTA); and metal carbonates such as sodium carbonate, potassium carbonate and potassium hydrogencarbonate. Additional compounds suitable for this purpose include ammonium salts such as ammonium nitrate, ammonium chloride, ammonium sulfate, ammonium phosphate and ammonium carbonate.

The temperature of the aqueous solution is preferably at least 20° C., more preferably at least 25° C. and even more preferably at least 30° C., but is preferably not more than 60° C., more preferably not more than 50° C. and even more preferably not more than 40° C. If the temperature is at least 20° C., the cost required for operating a refrigerator for cooling is not increased and the amount of ground water used for cooling can be suppressed. If the temperature is not more than 60° C., the corrosion resistance of the facilities can be easily ensured.

No particular limitation is imposed on the alternating current waveform used in the electrochemical graining treatment. For example, a sinusoidal, square, trapezoidal or triangular waveform may be used.

The frequency of the alternating current is preferably 10 to 200 Hz, more preferably 20 to 150 Hz and even more preferably 50 to 60 Hz. If the frequency is 10 Hz or more, large pits of a facetted (squarish) shape are hard to form, resulting in a more excellent scumming resistance. At a frequency of 200 Hz or less, the electrolytic current is not susceptible to inductance components of a circuit through which the current is passed and the production of a power supply of high capacity is thus facilitated.

“Trapezoidal waveform” refers herein to such a waveform as shown in FIG. 2. In the trapezoidal waveform, the time TP in which the current value changes from zero to a peak is preferably 0.3 to 2.0 msec and more preferably 0.5 to 0.8-msec. If the time is at least 0.3 msec, the cost required for the production of a power supply is decreased. If the time is not more than 2 msec, a higher uniformity of pits is attained. In the case of triangular waveform, the current rise time can be set as appropriate.

As the power supply equipment, a power supply using a commercial alternating current or an inverter-controlled power supply can be used, for example. Among others, an inverter-controlled power supply using an insulated gate bipolar transistor (IGBT) is preferable because any waveform can be generated under the pulse width modulation (PWM) control in the equipment. Moreover, such a power supply is excellent in follow-up performance when the current value (current density in the aluminum plate) is kept constant by changing the voltage in accordance with the width and thickness of the aluminum plate, the variation in concentration of the individual components in the electrolyte solution, and so forth.

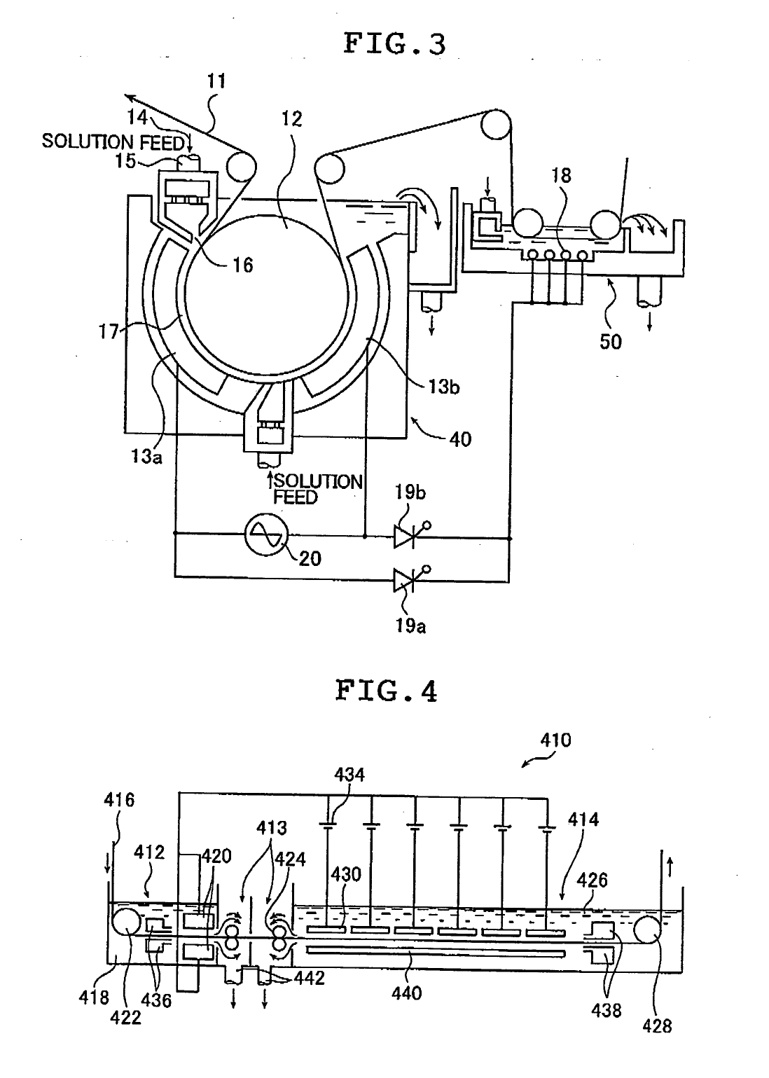

FIG. 3 is a schematic view of a radial electrolytic cell such as may be employed to carry out electrochemical graining treatment using alternating current in the method of manufacturing a lithographic printing plate support according to the present invention.

One or more AC power supplies may be connected to the electrolytic cell. To control the anode/cathode current ratio of the alternating current applied to the aluminum plate opposite the main electrodes and thereby carry out uniform graining and to dissolve carbon from the main electrodes, it is advantageous to provide an auxiliary anode and divert some of the alternating current, as shown in FIG. 3. FIG. 3 shows an aluminum plate 11, a radial drum roller 12, main electrodes 13a and 13b, an electrolytic treatment solution 14, a solution feed inlet 15, a slit 16, a solution channel 17, an auxiliary anode 18, thyristors 19a and 19b, an AC power supply 20, a main electrolytic cell 40 and an auxiliary anode cell 50. By using a rectifying or switching device to divert some of the current as direct current to the auxiliary anode provided in the separate cell from that containing the two main electrodes, it is possible to control the ratio between the current value when the aluminum plate opposite the main electrodes serves as an anode and the current value when the aluminum plate serves as a cathode. The current ratio (ratio between the total amount of electricity when the aluminum plate serves as an anode and the total amount of electricity when the aluminum plate serves as a cathode) is preferably 0.9 to 3 and more preferably 0.9 to 1.0.

Any known electrolytic cell employed for surface treatment, including vertical, flat and radial type electrolytic cells, may be used in the method of manufacturing a lithographic printing plate support of the present invention. Radial-type electrolytic cells such as described in JP 5-195300 A are especially preferred. The electrolyte solution passes through the electrolytic cell either parallel or counter to the direction in which the aluminum web advances.

The electrolytic cell may be divided into sections. In that case, electrolysis may be carried out in the respective sections under the same or different conditions.

Following completion of electrochemical graining treatment, it is desirable to remove the solution from the aluminum plate with nip rollers, rinse the plate with water for 1 to 10 seconds, then remove the water with nip rollers.

Rinsing treatment is preferably carried out using a spray line. The spray line used in rinsing treatment is typically one having a plurality of spray tips disposed along the width of the aluminum plate, each of which discharges a fanned-out spray of water. The interval between the spray tips is preferably 20 to 100 mm, and the amount of water discharged per spray tip is preferably 1 to 20 L/min. The use of a plurality of spray lines is preferred.

<Second Etching Treatment>

The purpose of the second etching treatment carried out after electrochemical graining treatment is to dissolve smut that arises in the electrochemical graining treatment and to dissolve the edges of the pits formed by the electrochemical graining treatment.

The second etching treatment is basically the same as the first etching treatment but the etching amount is preferably at least 0.05 g/m² and more preferably at least 0.1 g/m², but preferably not more than 0.5 g/m². In the etching amount of at least 0.05 g/m², edge portions of the pits formed by electrochemical graining treatment are smoothed and ink is hardly caught on the edge portions, leading to excellent scumming resistance. In the etching amount of not more than 0.5 g/m², asperities formed by electrochemical graining treatment are sufficiently retained to enhance the press life.

The concentration of the alkali solution is preferably at least 30 g/L and more preferably at least 300 g/L but preferably not more than 500 g/L and more preferably not more than 450 g/L.

The alkali solution contains preferably aluminum ions. The aluminum ion concentration in the alkali solution is preferably at least 1 g/L and more preferably at least 50 g/L but preferably not more than 200 g/L and more preferably not more than 150 g/L.

<Second Desmutting Treatment>

After the second etching treatment has been carried out, it is preferable to carry out acid pickling (second desmutting treatment) to remove contaminants (smut) remaining on the surface of the aluminum plate. The second desmutting treatment can basically be carried out in the same way as the first desmutting treatment.

If the desmutting treatment solution used in the second desmutting treatment is the same type of solution as the electrolyte solution used in anodizing treatment subsequently carried out, removal of the solution with nip rollers and rinsing may not be performed on the plate after the desmutting treatment.

The second desmutting treatment is preferably carried out in an electrolytic cell of an anodizing apparatus used in anodizing treatment to be described later, in which cell the aluminum plate is to be subjected to cathodic reaction. This configuration eliminates the necessity for providing an independent desmutting treatment cell for the second desmutting treatment, which can lead to equipment cost reduction.

<Anodizing Treatment>

The aluminum plate treated as described above is further subjected to anodizing treatment. Anodizing treatment can be carried out by any suitable method used in the field to which the present invention pertains. More specifically, an anodized layer can be formed on the aluminum plate surface by, for example, passing a current through the aluminum plate as an anode in a solution having a sulfuric acid concentration of 50 to 300 g/L and an aluminum concentration of up to 5 wt %. The solution used for anodizing treatment may include sulfuric acid, phosphoric acid, chromic acid, oxalic acid, sulfamic acid, benzenesulfonic acid, amidosulfonic acid or the like alone or in combination.

In this connection, components ordinarily present in at least the aluminum plate, electrodes, tap water, ground water and the like are acceptable in the electrolyte solution. In addition, secondary and tertiary components may be added. Examples of the “secondary and tertiary components” include ions of such a metal as sodium, potassium, magnesium, lithium, calcium, titanium, aluminum, vanadium, chromium, manganese, iron, cobalt, nickel, copper and zinc; cations such as ammonium ions; and anions such as nitrate ions, carbonate ions, chloride ions, phosphate ions, fluoride ions, sulfite ions, titanate ions, silicate ions and borate ions. These may be present in a concentration of about 0 to 10,000 ppm.

The anodizing treatment conditions vary empirically according to the electrolyte solution used, although it is generally suitable for the electrolyte solution to have a concentration of 1 to 80 wt % and a temperature of 5 to 70° C., and for the current density to be 0.5 to 60 A/dm², the voltage to be 1 to 100 V, and the electrolysis time to be 15 seconds to 50 minutes. These conditions may be adjusted to obtain the desired anodized layer weight.

Methods that may be used to carry out anodizing treatment include those described in JP 54-81133 A, JP 57-47894 A, JP 57-51289 A, JP 57-51290 A, JP 57-54300 A, JP 57-136596 A, JP 58-107498 A, JP 60-200256 A, JP 62-136596 A, JP 63-176494 A, JP 4-176897 A, JP 4-280997 A, JP 6-207299 A, JP 5-24377 A, JP 5-32083 A, JP 5-125597 A and JP 5-195291 A.

Among others, it is preferable to use a sulfuric acid solution as the electrolyte solution, as described in JP 54-12853 A and JP 48-45303 A. The electrolyte solution has a sulfuric acid concentration of preferably 10 to 300 g/L (1 to 30 wt %), and more preferably 50 to 200 g/L (5 to 20 wt %), and an aluminum ion concentration of preferably 1 to 25 g/L (0.1 to 2.5 wt %), and more preferably 2 to 10 g/L (0.2 to 1 wt %). Such an electrolyte solution can be prepared by, for instance, adding aluminum sulfate to a dilute sulfuric acid having a sulfuric acid concentration of 50 to 200 g/L.

Control of the electrolyte solution composition is preferably carried out using a method similar to that employed in the nitric acid electrolysis as described before. That is, the composition is preferably controlled based on the electrical conductivity, specific gravity and temperature, or on the electrical conductivity, ultrasonic wave propagation velocity and temperature, which parameters are corresponding to a matrix of the sulfuric acid concentration and the aluminum ion concentration.

The electrolyte solution has a temperature of preferably 25 to 55° C., and more preferably 30 to 50° C.

When anodizing treatment is carried out in an electrolyte solution containing sulfuric acid, direct current or alternating current may be applied across the aluminum plate and the counter electrode.

When a direct current is applied to the aluminum plate, the current density is preferably 1 to 60 A/dm², and more preferably 5 to 40 A/dm².

To keep burnt deposits (areas of the anodized layer which are thicker than surrounding areas) from arising on portions of the aluminum plate due to the concentration of current when anodizing treatment is carried out as a continuous process, it is preferable to apply current at a low density of 5 to 10 A/dm² at the start of anodizing treatment and to increase the current density to 30 to 50 A/dm² or more as anodizing treatment proceeds.

Specifically, it is preferable for current from the DC power supplies to be allocated such that current from downstream DC power supplies is equal to or greater than current from upstream DC power supplies. Current allocation in this way will discourage the formation of burnt deposits, enabling high-speed anodization to be carried out.

When anodizing treatment is carried out as a continuous process, this is preferably done using a system that supplies power to the aluminum plate through the electrolyte solution.

By carrying out anodizing treatment under such conditions, a porous film with numerous micropores can be obtained. The film generally has an average pore diameter of about 5 to 50 nm and an average pore density of about 300 to 800 pores/m².

The weight of the anodized layer is preferably 1 to 5 g/m². At a weight of 1 g/m² or more, scratches are not readily formed on the plate. A weight of not more than 5 g/m² does not require a large amount of electrical power for the formation of the layer, which is economically advantageous. An anodized layer weight of 1.5 to 4 g/m² is more preferred. It is also desirable for anodizing treatment to be carried out in such a way that the difference in the anodized layer weight between the center of the aluminum plate and the areas near the edges is not more than 1 g/m².

The weight of the anodized layer on the rear side of the aluminum plate that is opposite to the surface having been subjected to electrochemical graining treatment is preferably 0.1 to 1 g/m². At a weight of 0.1 g/m² or more, scratches are not readily formed on the rear surface and hence when the presensitized plates are stacked on top of each other, scuffing of the image recording layer brought into contact with the rear surface is prevented. A weight of not more than 1 g/m² is economically advantageous.

Examples of electrolyzing apparatuses that may be used in anodizing treatment include those described in JP 48-26638 A, JP 47-18739 A, JP 58-24517 B and JP 2001-11698 A.

Among others, an apparatus like that shown in FIG. 4 is preferred. FIG. 4 is a schematic view showing an exemplary apparatus for anodizing the surface of an aluminum plate.

In an anodizing apparatus 410 shown in FIG. 4, to apply a current to an aluminum plate 416 through an electrolyte solution, a power supplying cell 412 is disposed upstream in the direction of advance of the aluminum plate 416 and an anodizing treatment tank 414 downstream. The aluminum plate 416 is moved by path rollers 422 and 428 in the direction indicated by the arrows in FIG. 4. The power supplying cell 412 through which the aluminum plate 416 first passes is provided with anodes 420 which are connected to the positive poles of a DC power supply 434, and the aluminum plate 416 serves as the cathode in the cell. Hence, a cathodic reaction arises at the aluminum plate 416.

The anodizing treatment tank 414 through which the aluminum plate 416 next passes is provided with a cathode 430 which is connected to the negative pole of the DC power supply 434, and the aluminum plate 416 serves as the anode in the tank. Hence, an anodic reaction arises at the aluminum plate 416, and an anodized layer is formed on the surface of the aluminum plate 416. The aluminum plate 416 is at a distance of preferably 50 to 200 mm from the cathode 430. The cathode 430 is made of aluminum. To facilitate the venting of hydrogen gas generated by the anodic reaction from the system, it is preferable for the cathode 430 to be divided into a plurality of sections in the direction of advance of the aluminum plate 416 rather than to be a single electrode having a broad surface area.

As shown in FIG. 4, it is advantageous to provide, between the power supplying cell 412 and the anodizing treatment tank 414, an intermediate tank 413 that does not hold the electrolyte solution. By providing the intermediate tank 413, the current can be kept from passing directly from the anode 420 to the cathode 430 and bypassing the aluminum plate 416. It is preferable to minimize the bypass current by providing nip rollers 424 in the intermediate tank 413 to remove the solution from the aluminum plate 416. The electrolyte solution removed by the nip rollers 424 is discharged outside the anodizing apparatus 410 through a discharge outlet 442.

To lower the voltage loss, an electrolyte solution 418 contained in the power supplying cell 412 is set at a higher temperature and/or concentration than an electrolyte solution 426 contained in the anodizing treatment tank 414. Moreover, the composition, temperature and other characteristics of the electrolyte solutions 418 and 426 are set based on such considerations as the anodized layer forming efficiency, the shapes of micropores in the anodized layer, the hardness of the anodized layer, the voltage, and the cost of the electrolyte solution.

The power supplying cell 412 and the anodizing treatment tank 414 are supplied with electrolyte solutions injected by solution feed nozzles 436 and 438. To ensure that the distribution of electrolyte solution remains uniform and thereby prevent the localized concentration of current on the aluminum plate 416 in the anodizing treatment tank 414, the solution feed nozzles 436 and 438 have a construction in which slits are provided to keep the flow of injected liquid constant in the width direction.

In the anodizing treatment tank 414, a shield 440 is provided on the opposite side of the aluminum plate 416 from the cathode 430 to check the flow of current to the opposite surface of the aluminum plate 416 with the surface on which an anodized layer is to be formed. The interval between the aluminum plate 416 and the shield 440 is preferably 5 to 30 mm. It is preferable to use a plurality of DC power supplies as the DC power supply 434, with their positive poles being connected in common, thereby enabling control of the current distribution within the anodizing treatment tank 414.

When anodizing treatment is carried out, one anodizing apparatus 410 may be used but anodizing treatment is preferably carried out as a continuous process by arranging two to five anodizing apparatuses 410 in series in the direction in which the aluminum plate advances. This is effective in high speed processing and reduction of electric power used.

<Sealing Treatment>

In the present invention, sealing treatment may be carried out as required to seal micropores in the anodized layer. Such treatment can enhance the developability (sensitivity) of the presensitized plate.

Anodized layers are known to be porous films having micropores which extend in a direction substantially perpendicular to the surface of the film. In the present invention, it is advantageous to carry out sealing treatment to a high sealing ratio following the anodizing treatment. The sealing ratio is preferably at least 50%, more preferably at least 70%, and even more preferably at least 90%. “Sealing ratio,” as used herein, is defined as follows.
Sealing ratio=[(surface area before sealing)−(surface area after sealing)]/(surface area before sealing)×100%

The surface area can be measured using a simple BET-type surface area analyzer, such as Quantasorb (Yuasa Ionics Inc.).

Sealing may be carried out using any known method without particular limitation. Illustrative examples of sealing methods that may be used include hot water treatment, boiling water treatment, steam treatment, dichromate treatment, nitrite treatment, ammonium acetate treatment, electrodeposition sealing treatment, hexafluorozirconic acid treatment like that described in JP 36-22063 B, treatment with an aqueous solution containing a phosphate and an inorganic fluorine compound as described in JP 9-244227 A, treatment with a sugar-containing aqueous solution as described in JP 9-134002 A, treatment with a titanium and fluorine-containing aqueous solution as described in JP 2000-81704 A and JP 2000-89466 A, and alkali metal silicate treatment like that described in U.S. Pat. No. 3,181,461.

One preferred type of sealing treatment is alkali metal silicate treatment. This can be carried out using a pH 10 to 13 aqueous solution of an alkali metal silicate at 25° C. that does not undergo solution gelation or dissolve the anodized layer, and by suitably selecting the treatment conditions, such as the alkali metal silicate concentration, the treatment temperature and the treatment time. Preferred alkali metal silicates include sodium silicate, potassium silicate and lithium silicate. Sodium hydroxide, potassium hydroxide, lithium hydroxide or the like may be incorporated in the aqueous solution of alkali metal silicate in order to increase the pH thereof.

If necessary, an alkaline earth metal salt and/or a Group 4 (Group IVA) metal salt may also be included in the aqueous alkali metal silicate solution. Examples of suitable alkaline earth metal salts include the following water-soluble salts: nitrates such as calcium nitrate, strontium nitrate, magnesium nitrate and barium nitrate; and also sulfates, hydrochlorides, phosphates, acetates, oxalates, and borates of alkaline earth metals. Exemplary Group 4 (Group IVA) metal salts include titanium tetrachloride, titanium trichloride, titanium potassium fluoride, titanium potassium oxalate, titanium sulfate, titanium tetraiodide, zirconyl chloride, zirconium dioxide and zirconium tetrachloride. These alkaline earth metal salts and Group 4 (Group IVA) metal salts may be used singly or in combinations of two or more thereof.

The concentration of the aqueous alkali metal silicate solution is preferably 0.01 to 10 wt %, and more preferably 0.05 to 5.0 wt %.

Another preferred type of sealing treatment is hexafluorozirconic acid treatment. Such treatment is carried out using a hexafluorozirconate such as sodium hexafluorozirconate and potassium hexafluorozirconate. It is particularly preferable to use sodium hexafluorozirconate. This treatment provides the presensitized plate with excellent developability (sensitivity). The hexafluorozirconate solution used in this treatment has a concentration of preferably 0.01 to 2 wt %, and more preferably 0.1 to 0.3 wt %.

It is desirable for the hexafluorozirconate solution to contain sodium dihydrogenphosphate in a concentration of preferably 0.01 to 3 wt %, and more preferably 0.1 to 0.3 wt %.

The hexafluorozirconate solution may contain aluminum ions. In this case, the hexafluorozirconate solution has preferably an aluminum ion concentration of 1 to 500 mg/L.

The sealing treatment temperature is preferably 20 to 90° C., and more preferably 50 to 80° C.

The sealing treatment time (period of immersion in the solution) is preferably 1 to 20 seconds, and more preferably 5 to 15 seconds.

If necessary, sealing treatment may be followed by surface treatment such as the above-described alkali metal-silicate treatment or treatment in which the aluminum plate is immersed in or coated with a solution containing polyvinylphosphonic acid, polyacrylic acid, a polymer or copolymer having pendant groups such as sulfo groups, or any of the organic compounds, or salts thereof, as described in JP 11-231509 A which has an amino group and a phosphine group, phosphone group or phosphoric acid group.

Following sealing treatment, it is desirable to carry out hydrophilizing treatment described below.

<Hydrophilizing Treatment>

Hydrophilizing treatment may be carried out after anodizing treatment or sealing treatment. Illustrative examples of suitable hydrophilizing treatments include the potassium hexafluorozirconate treatment described in U.S. Pat. No. 2,946,638, the phosphomolybdate treatment described in U.S. Pat. No. 3,201,247, the alkyl titanate treatment described in GB 1,108,559, the polyacrylic acid treatment described in DE 1,091,433, the polyvinylphosphonic acid treatments described in DE 1,134,093 and GB 1,230,447, the phosphonic acid treatment described in JP 44-6409 B, the phytic acid treatment described in U.S. Pat. No. 3,307,951, the treatments involving the divalent metal salt of a lipophilic organic polymeric compound described in JP 58-16893 A and JP 58-18291 A, a treatment like that described in U.S. Pat. No. 3,860,426 in which an undercoat of a hydrophilic cellulose (e.g., carboxymethyl cellulose) containing a water-soluble metal salt (e.g., zinc acetate) is provided, and the treatment as described in JP 59-101651 A in which a sulfo group-bearing water-soluble polymer is undercoated.

Additional examples of suitable hydrophilizing treatments include undercoating treatment using the phosphates described in JP 62-019494 A, the water-soluble epoxy compounds described in JP 62-033692 A, the phosphoric acid-modified starches described in JP 62-097892 A, the diamine compounds described in JP 63-056498 A, the inorganic or organic salts of amino acids described in JP 63-130391 A, the carboxy or hydroxy group-bearing organic phosphonic acids described in JP 63-145092 A, the amino group and phosphonic acid group-bearing compounds described in JP 63-165183 A, the specific carboxylic acid derivatives described in JP 2-316290 A, the phosphate esters described in JP 3-215095 A, the compounds having one amino group and one phosphorus oxoacid group described in JP 3-261592 A, the aliphatic or aromatic phosphonic acids (e.g., phenylphosphonic acid) described in JP 5-246171 A, the sulfur atom-bearing compounds (e.g., thiosalicylic acid) described in JP 1-307745 A, and the phosphorus oxoacid group-bearing compounds described in JP 4-282637 A.

Coloration with an acid dye as described in JP 60-64352 A may also be carried out.

It is preferable to carry out hydrophilizing treatment by a method in which the aluminum plate is immersed in an aqueous solution of an alkali metal silicate such as sodium silicate or potassium silicate, or is coated with a hydrophilic vinyl polymer or some other hydrophilic compound so as to form a hydrophilic undercoat.

Hydrophilizing treatment with an aqueous solution of an alkali metal silicate such as sodium silicate or potassium silicate can be carried out according to the processes and procedures described in U.S. Pat. No. 2,714,066 and U.S. Pat. No. 3,181,461.

Illustrative examples of suitable alkali metal silicates include sodium silicate, potassium silicate and lithium silicate. Suitable amounts of sodium hydroxide, potassium hydroxide, lithium hydroxide or the like may be included in the aqueous alkali metal silicate solution.

An alkaline earth metal salt or a Group 4 (Group IVA) metal salt may also be included in the aqueous alkali metal silicate solution. Examples of suitable alkaline earth metal salts include nitrates such as calcium nitrate, strontium nitrate, magnesium nitrate and barium nitrate; and also sulfates, hydrochlorides, phosphates, acetates, oxalates, and borates. Exemplary Group 4 (Group IVA) metal salts include titanium tetrachloride, titanium trichloride, titanium potassium fluoride, titanium potassium oxalate, titanium sulfate, titanium tetraiodide, zirconyl chloride, zirconium dioxide and zirconium tetrachloride. These alkaline earth metal salts and Group 4 (Group IVA) metal salts may be used singly or in combinations of two or more thereof.

The amount of silicon adsorbed as a result of alkali metal silicate treatment can be measured with a fluorescent x-ray analyzer, and is preferably about 1.0 to 15.0 mg/m².

This alkali metal silicate treatment has the effect of enhancing the resistance at the surface of the lithographic printing plate support to dissolution by the alkaline developer, suppressing the leaching of aluminum ingredients into the developer, and reducing the generation of development scum due to developer fatigue.

Hydrophilizing treatment involving the formation of a hydrophilic undercoat can also be carried out in accordance with the conditions and procedures described in JP 59-101651 A and JP 60-149491 A.

Hydrophilic vinyl polymers that may be used in such a method include copolymers of a sulfo group-bearing vinyl polymerizable compound such as polyvinylsulfonic acid or sulfo group-bearing p-styrenesulfonic acid with a conventional vinyl polymerizable compound such as an alkyl (meth)acrylate. Examples of hydrophilic compounds that may be used in this method include compounds having at least one group selected from among —NH₂ groups, —COOH groups and sulfo groups.

<Drying>

After the lithographic printing plate support has been obtained as described above, it is advantageous to dry the surface of the support before providing an image recording layer thereon. Drying is preferably carried out after the support has been rinsed with water and the water removed with nip rollers or an air knife following the final surface treatment.

The drying temperature is preferably at least 70° C., and more preferably at least 80° C., but preferably not more than 110° C., and more preferably not more than 100° C.

The drying time is preferably in the range of 2 seconds to 15 seconds.

[Presensitized Plate]

The lithographic printing plate support according to the present invention can be formed into a presensitized plate of the present invention by providing an image recording layer thereon. A photosensitive composition is used in the image recording layer.

Preferred examples of photosensitive compositions that may be used in the present invention include thermal positive-type photosensitive compositions containing an alkali-soluble polymeric compound and a photothermal conversion substance (such compositions and the image recording layers obtained using these compositions are referred to below as “thermal positive-type” compositions and image recording layers), thermal negative-type photosensitive compositions containing a curable compound and a photothermal conversion substance (these compositions and the image recording layers obtained therefrom are similarly referred to below as “thermal negative-type” compositions and image recording layers), photopolymerizable photosensitive compositions (referred to below as “photopolymer-type” compositions), negative-type photosensitive compositions containing a diazo resin or a photo-crosslinkable resin (referred to below as “conventional negative-type” compositions), positive-type photosensitive compositions containing a quinonediazide compound (referred to below as “conventional positive-type” compositions), and photosensitive compositions that do not require a special development step (referred to below as “non-treatment type” compositions). The thermal positive-type, thermal negative-type and non-treatment type compositions are particularly preferred. These preferred photosensitive compositions are described below.

<Thermal Positive-Type Photosensitive Compositions>

<Photosensitive Layer>

Thermal positive-type photosensitive compositions contain an alkali-soluble polymeric compound and a photothermal conversion substance. In a thermal positive-type image recording layer, the photothermal conversion substance converts light energy such as from an infrared laser into heat, which efficiently eliminates interactions that lower the alkali solubility of the alkali-soluble polymeric compound.

The alkali-soluble polymeric compound may bet for example, a resin having an acidic group on the molecule, or a mixture of two or more such resins. Resins having an acidic group, such as a phenolic hydroxy group, a sulfonamide group (—SO₂NH—R, wherein R is a hydrocarbon group) or an active imino group (—SO₂NHCOR, —SO₂NHSO₂R or —CONHSO₂R, wherein R is as defined above), are especially preferred on account of their solubility in alkaline developers.

For an excellent image formability with exposure to light from an infrared laser, for example, resins having phenolic hydroxy groups are especially desirable. Preferred examples of such resins include novolak resins such as phenol-formaldehyde resins, m-cresol-formaldehyde resins, p-cresol-formaldehyde resins, cresol-formaldehyde resins in which the cresol is a mixture of m-cresol and p-cresol, and phenol/cresol mixture-formaldehyde resins (phenol-cresol-formaldehyde co-condensation resins) in which the cresol is m-cresol, p-cresol or a mixture of m- and p-cresol.

Additional preferred examples include the polymeric compounds described in JP 2001-305722 A (especially paragraphs [0023] to [0042]), the polymeric compounds having recurring units of general formula (1) described in JP 2001-215693 A, and the polymeric compounds described in JP 2002-311570 A (especially paragraph [0107]).

To provide a good recording sensitivity, the photothermal conversion substance is preferably a pigment or dye that absorbs light in the infrared wavelength range of 700 to 1200 nm. Illustrative examples of suitable dyes include azo dyes, metal complex azo dyes, pyrazolone azo dyes, naphthoquinone dyes, anthraquinone dyes, phthalocyanine dyes, carbonium dyes, quinoneimine dyes, methine dyes, cyanine dyes, squarylium dyes, pyrylium salts and metal-thiolate complexes (e.g., nickel-thiolate complexes). Of these, cyanine dyes are preferred. The cyanine dyes of general formula (I) described in JP 2001-305722 A are especially preferred.

A dissolution inhibitor may be included in thermal positive-type photosensitive compositions. Preferred examples of dissolution inhibitors include those described in paragraphs [0053) to [0055] of JP 2001-305722 A.

The thermal positive-type photosensitive compositions preferably also include, as additives, sensitivity regulators, print-out agents for obtaining a visible image immediately after heating from light exposure, compounds such as dyes as image colorants, and surfactants for enhancing coatability and treatment stability. Compounds such as described in paragraphs [0056] to [0060] of JP 2001-305722 A are preferred additives.

Use of the photosensitive compositions described in detail in JP 2001-305722 A is desirable because of the above preferred components and additional advantages.

The thermal positive-type image recording layer is not limited to a single layer, but may have a two-layer construction.

Preferred examples of image recording layers with a two-layer construction (also referred to as “multilayer-type image recording layers”) include those comprising a bottom layer (“layer A”) of excellent press life and solvent resistance which is provided on the side close to the support and a layer (“layer B”) having an excellent positive-image formability which is provided on layer A. This type of image recording layer has a high sensitivity and can provide a broad development latitude. Layer B generally contains a photothermal conversion substance. Preferred examples of the photothermal conversion substance include the dyes mentioned above.

Preferred examples of resins that may be used in layer A include polymers that contain as a copolymerizable component a monomer having a sulfonamide group, an active imino group or a phenolic hydroxy group; such polymers have an excellent press life and solvent resistance. Preferred examples of resins that may be used in layer B include phenolic hydroxy group-bearing resins which are soluble in aqueous alkali solutions.

In addition to the above resins, various additives may be included, if necessary, in the compositions used to form layers A and B. For example, suitable use can be made of the additives described in paragraphs (0062] to [0085] of JP 2002-323769 A. The additives described in paragraphs [0053] to [0060] of JP 2001-305722 A as above are also suitable for use.

The components and proportions thereof in each of layers A and B are preferably selected as described in JP 11-218914 A.

<Intermediate Layer>

It is advantageous to provide an intermediate layer between the thermal positive-type image recording layer and the support. Preferred examples of ingredients that may be used in the intermediate layer include the various organic compounds described in paragraph [0068] of JP 2001-305722 A.

<Others>

The methods described in detail in JP 2001-305722 A may be used to form a thermal positive-type image recording layer and to make a printing plate having such a layer.

<Thermal Negative-Type Photosensitive Compositions>

Thermal negative-type photosensitive compositions contain a curable compound and a photothermal conversion substance. A thermal negative-type image recording layer is a negative-type photosensitive layer in which areas irradiated with light such as from an infrared laser cure to form image areas.

<Polymerizable Layer>

An example of a preferred thermal negative-type image recording layer is a polymerizable image recording layer (polymerizable layer). The polymerizable layer contains a photothermal conversion substance, a radical generator, a radical-polymerizable compound which is a curable compound, and a binder polymer. In the polymerizable layer, the photothermal conversion substance converts absorbed infrared light into heat, and the heat decomposes the radical generator, thereby generating radicals. The radicals then trigger the chain polymerization and curing of the radical-polymerizable compound.

Illustrative examples of the photothermal conversion substance include photothermal conversion substances that may be used in the above-described thermal positive-type photosensitive compositions. Specific examples of cyanine dyes, which are especially preferred, include those described in paragraphs [0017] to [0019] of JP 2001-133969 A.

Preferred radical generators include onium salts. The onium salts described in paragraphs [0030] to [0033] of JP 2001-133969 A are especially preferred.

Exemplary radical-polymerizable compounds include compounds having one, and preferably two or more, terminal ethylenically unsaturated bonds.

Preferred binder polymers include linear organic polymers. Linear organic polymers which are soluble or swellable in water or a weak alkali solution in water are preferred. Of these, (meth)acrylic resins having unsaturated groups (e.g., allyl, acryloyl) or benzyl groups and carboxy groups in side chains are especially preferred because they provide an excellent balance of film strength, sensitivity and developability.

Radical-polymerizable compounds and binder polymers that may be used include those described specifically in paragraphs [0036] to [0060] of JP 2001-133969 A.

Thermal negative-type photosensitive compositions preferably contain additives described in paragraphs [0061] to [0068] of JP 2001-133969 A (e.g., surfactants for enhancing coatability).

The methods described in detail in JP 2001-133969 A may be used to form a polymerizable layer and to make a printing plate having such a layer.

<Acid-Crosslinkable Layer>

Another preferred thermal negative-type image recording layer is an acid-crosslinkable image recording layer (abbreviated hereinafter as “acid-crosslinkable layer”). An acid-crosslinkable layer contains a photothermal conversion substance, a thermal acid generator, a compound (crosslinker) which is curable and which crosslinks under the influence of an acid, and an alkali-soluble polymeric compound which is capable of reacting with the crosslinker in the presence of an acid. In an acid-crosslinkable layer, the photothermal conversion substance converts absorbed infrared light into heat. The heat decomposes the thermal acid generator, thereby generating an acid which causes the crosslinker and the alkali-soluble polymeric compound to react and cure.

The photothermal conversion substance is exemplified by the same substances as can be used in the polymerizable layer.

Exemplary thermal acid generators include photoinitiators for photopolymerization, dye photochromogenic substances, and heat-decomposable compounds such as acid generators which are used in microresists and the like.

Exemplary crosslinkers include hydroxymethyl- or alkoxymethyl-substituted aromatic compounds, compounds having N-hydroxymethyl, N-alkoxymethyl or N-acyloxymethyl groups, and epoxy compounds.

Exemplary alkali-soluble polymeric compounds include novolak resins and polymers having hydroxyaryl groups in side chains.

<Photopolymer-Type Photosensitive Compositions>

Photopolymer-type photosensitive compositions contain an addition-polymerizable compound, a photopolymerization initiator and a polymer binder.

Preferred addition-polymerizable compounds include compounds containing an ethylenically unsaturated bond which are addition-polymerizable. Ethylenically unsaturated bond-containing compounds are compounds which have a terminal ethylenically unsaturated bond. Such compounds may have the chemical form of a monomer, a prepolymer, or a mixture thereof. The monomers are exemplified by esters of unsaturated carboxylic acids (e.g., acrylic acid, methacrylic acid, itaconic acid, maleic acid) and aliphatic polyols, and amides of unsaturated carboxylic acids and aliphatic polyamines.

Preferred addition-polymerizable compounds include also urethane-type addition-polymerizable compounds.

The photopolymerization initiator may be any of various photopolymerization initiators or a system of two or more photopolymerization initiators (photoinitiation system) which is suitably selected according to the wavelength of the light source to be used. Preferred examples include the initiation systems described in paragraphs [0021] to (0023) of JP 2001-22079 A.

The polymer binder, inasmuch as it must function as a film-forming agent for the photopolymerizable photosensitive composition and, at the same time, must allow the image recording layer to dissolve in an alkaline developer, should be an organic polymer which is soluble or swellable in an aqueous alkali solution. Preferred examples of such organic polymers include those described in paragraphs [0036] to [0063] of JP 2001-22079 A.

It is preferable for the photopolymer-type photosensitive composition to include the additives described in paragraphs [0079] to [0088] of JP 2001-22079 A (e.g., surfactants for improving coatability, colorants, plasticizers, thermal polymerization inhibitors).

To prevent the inhibition of polymerization by oxygen, it is preferable to provide an oxygen-blocking protective layer on top of the photopolymer-type image recording layer. The polymer present in the oxygen-blocking protective layer is exemplified by polyvinyl alcohols and copolymers thereof.

It is also desirable to provide an intermediate layer or a bonding layer like those described in paragraphs [0124] to [0165] of JP 2001-228608 A.

<Conventional Negative-Type Photosensitive Compositions>

Conventional negative-type photosensitive compositions contain a diazo resin or a photo-crosslinkable resin. Among others, photosensitive compositions which contain a diazo resin and an alkali-soluble or -swellable polymeric compound (binder) are preferred.

The diazo resin is exemplified by condensation products of an aromatic diazonium salt with an active carbonyl group-bearing compound such as formaldehyde; and organic solvent-soluble diazo resin inorganic salts which are the reaction products of a hexafluorophosphate or tetrafluoroborate with the condensation product of a p-diazophenylamine and formaldehyde. The high-molecular-weight diazo compounds described in JP 59-78340 A, in which the content of hexamer and larger polymers is at least 20 mol %, are especially preferred.

Exemplary binders include copolymers containing acrylic acid, methacrylic acid, crotonic acid or maleic acid as an essential component. Specific examples include the multi-component copolymers of such monomers as 2-hydroxyethyl (meth)acrylate, (meth)acrylonitrile and (meth)acrylic acid described in JP 50-118802 A, and the multi-component copolymers of alkyl acrylates, (meth)acrylonitrile and unsaturated carboxylic acids described in JP 56-4144 A.

Conventional negative-type photosensitive compositions preferably contain as additives the print-out agents, dyes, plasticizers for imparting flexibility and wear resistance to the applied coat, development promoters and other compounds, and the surfactants for enhancing coatability described in paragraphs [0014] to [0015] of JP 7-281425 A.

Below the conventional negative-type photosensitive layer, it is advantageous to provide the intermediate layer which contains a polymeric compound having an acid group-bearing component and an onium group-bearing component described in JP 2000-105462 A.

<Conventional Positive-Type Photosensitive Compositions>

Conventional positive-type photosensitive compositions contain a quinonediazide compound. Photosensitive compositions containing an o-quinonediazide compound and an alkali-soluble polymeric compound are especially preferred.

Illustrative examples of the o-quinonediazide compound include esters of 1,2-naphthoquinone-2-diazido-5-sulfonylchloride and a phenol-formaldehyde resin or a cresol-formaldehyde resin, and the esters of 1,2-naphthoquinone-2 -diazido-5-sulfonylchloride and pyrogallol-acetone resins described in U.S. Pat. No. 3,635,709.

Illustrative examples of the alkali-soluble polymeric compound include phenol-formaldehyde resins, cresol-formaldehyde resins, phenol-cresol-formaldehyde co-condensation resins, polyhydroxystyrene, N-(4-hydroxyphenyl)methacrylamide copolymers, the carboxy group-bearing polymers described in JP 7-36184 A, the phenolic hydroxy group-bearing acrylic resins described in JP 51-34711 A, the sulfonamide group-bearing acrylic resins described in JP 2-866 A, and urethane resins.

Conventional positive-type photosensitive compositions preferably contain as additives the compounds such as sensitivity regulators, print-out agents and dyes described in paragraphs [0024] to [0027] of JP 7-92660 A, and surfactants for enhancing coatability such as those described in paragraph [0031] of JP 7-92660 A.

Below the conventional positive-type photosensitive layer, it is advantageous to provide an intermediate layer similar to the intermediate layer which is preferably used in the case of the conventional negative-type photosensitive layer as above.

<Non-Treatment Type Photosensitive Compositions>

Illustrative examples of non-treatment type photosensitive compositions include thermoplastic polymer powder-based photosensitive compositions, microcapsule-based photosensitive compositions, and sulfonic acid-generating polymer-containing photosensitive compositions. All of these are heat-sensitive compositions containing a photothermal conversion substance. The photothermal conversion substance is preferably a dye of the same type as those which can be used in the above-described thermal positive-type photosensitive compositions.

Thermoplastic polymer powder-based photosensitive compositions are composed of a hydrophobic, heat-meltable finely divided polymer dispersed in a hydrophilic polymer matrix. In the thermoplastic polymer powder-based image recording layer, the fine particles of hydrophobic polymer melt under the influence of heat generated by light exposure and mutually fuse, forming hydrophobic regions which serve as the image areas.

The finely divided polymer is preferably one in which the particles melt and fuse together under the influence of heat. A finely divided polymer in which the individual particles have a hydrophilic surface, enabling them to disperse in a hydrophilic component such as fountain solution, is especially preferred. Preferred examples include the finely divided thermoplastic polymers described in Research Disclosure No. 33303 (January 1992), JP 9-123387 A, JP 9-131850 A, JP 9-171249 A, JP 9-171250 A and EP 931,647 A. Of these, polystyrene and polymethyl methacrylate are preferred. Illustrative examples of finely divided polymers having a hydrophilic surface include those in which the polymer itself is hydrophilic, and those in which the surfaces of the polymer particles have been rendered hydrophilic by adsorbing thereon a hydrophilic compound such as polyvinyl alcohol or polyethylene glycol.

The finely divided polymer preferably has reactive functional groups.

Preferred examples of microcapsule-type photosensitive compositions include those described in JP 2000-118160 A, and compositions like those described in JP 2001-277740 A in which a compound having thermally reactive functional groups is enclosed within microcapsules.

Illustrative examples of sulfonic acid-generating polymers that may be used in sulfonic acid generating polymer-containing photosensitive compositions include the polymers described in JP 10-282672 A that have sulfonate ester groups, disulfone groups or sec- or tert-sulfonamide groups in side chains.

Including a hydrophilic resin in a non-treatment type photosensitive composition not only provides a good on-press developability, it also enhances the film strength of the photosensitive layer itself. Preferred hydrophilic resins include resins having hydrophilic groups such as hydroxy, carboxy, hydroxyethyl, hydroxypropyl, amino, aminoethyl, aminopropyl or carboxymethyl groups; and hydrophilic binder resins of a sol-gel conversion-type.

A non-treatment type image recording layer can be developed on the press, and thus does not require a special development step. The methods described in detail in JP 2002-178655 A may be used as the method of forming a non-treatment type image recording layer and the associated platemaking and printing methods.

<Back Coat>

If necessary, the presensitized plate of the invention obtained by providing any of the various above image recording layers on a lithographic printing plate support obtained according to the invention may be provided on the rear side with a coat composed of an organic polymeric compound to prevent scuffing of the image recording layer when the presensitized plates are stacked on top of each other.

[Lithographic Platemaking Process]

A lithographic printing plate is prepared from the presensitized plate comprising a lithographic printing plate support obtained according to this invention by any of various treatment methods, depending on the type of image recording layer.

Illustrative examples of sources of actinic light that may be used for imagewise exposure include mercury vapor lamps, metal halide lamps, xenon lamps and chemical lamps. Examples of laser beams that may be used include those from helium-neon lasers (He—Ne lasers), argon lasers, krypton lasers, helium-cadmium lasers, KrF excimer lasers, semiconductor lasers, YAG lasers and YAG-SHG lasers.

Following the above exposure, if the image recording layer is of a thermal positive type, thermal negative type, conventional negative type, conventional positive type or photopolymer type, it is preferable to carry out development using a developer in order to prepare a lithographic printing plate.

The developer is preferably an alkaline developer, and more preferably an alkaline aqueous solution which is substantially free of organic solvent.

Developers which are substantially free of alkali metal silicates are also preferred. One example of a suitable method of development using a developer which is substantially free of alkali metal silicates is the method described in detail in JP 11-109637 A.

Developers which contain an alkali metal silicate may also be used.

### EXAMPLES

Hereinafter, the present invention is described in detail with reference to non-limitative examples.

1. Manufacture of Aluminum Plate Embossing Roll

A roll of tool steel (SKD11) that had been quenched to a hardness of Hv750 was successively subjected to treatments (1) to (5) below, yielding an aluminum plate embossing roll.

(1) Mirror Polishing

Buffing was carried out as the mirror polishing process, thereby removing marks left by the grindstone used to abrade the surface of the roll. Of the buffed surface, the average roughness Rₐ was 0.2 μm and the maximum height Rₘₐₓ was 1 μm. The average roughness Rₐ and the maximum height Rₘₐₓ were measured according to the measurement procedures for the arithmetic mean deviation of the profile Rₐ and maximum height of the profile R_{y} defined in JIS B0601-1994.

(2) Blasting

The roll surface was subjected to graining treatment by air blasting it twice using a grit material composed of #80 mesh alumina particles. Each blast was carried out at an air pressure of 2 kgf/cm² (1.96×10⁵ Pa) and the average roughness Rₐ of the air-blasted surface was 0.8 μm.

(3) Degreasing

The roll was immersed for 30 seconds in a 30° C. degreaser liquid contained in a degreasing tank, and oil on the roll surface was removed with the liquid. The roll was then rinsed with water, after which air was blown over it to remove moisture.

(4) Electrolytic Treatment

The roll was subjected to electrolytic treatment by the application of continuous direct current to the roll as an anode in a 50° C. electrolyte solution containing 300 g/L of chromic acid, 2 g/L of sulfuric acid and 1 g/L of iron at a current density of 30 A/dm². The amount of electricity used in the electrolytic treatment was 10,000 C/dm².

The direct current was provided by the three-phase full-wave rectification of current waveform and then passed through a filter circuit before application so as to reduce its ripple component to 5% or less. Lead was used as the counter electrode. The roll was placed upright in the electrolyte solution, and the lead electrode was arranged in a cylindrical form so as to encircle it. The shaft portion of the roll was masked with vinyl chloride to keep it from undergoing electrolytic treatment.

(5) Chromium Plating

Next, chromium plating treatment was performed on the roll by the application of continuous direct current to the roll as a cathode in a 50° C. electrolyte solution containing 300 g/L of chromic acid, 2 g/L of sulfuric acid and 1 g/L of iron at a current density of 40 A/dm². The plating treatment time was so set as to give a plating thickness of 6 μm.

The direct current was provided by the three-phase full-wave rectification of current waveform and then passed through a filter circuit before application so as to reduce its ripple component to 5% or less. Lead was used as the counter electrode. The roll was placed upright in the electrolyte solution, and the lead electrode was arranged in a cylindrical form so as to encircle it. The shaft portion of the roll was masked with vinyl chloride to keep it from undergoing plating treatment.

2. Fabrication of Aluminum Plate

A melt was prepared from each aluminum alloy comprising the respective components shown in Table 1. The aluminum alloy melt was subjected to molten metal treatment and filtration, then was cast into a 500 mm thick, 1,200 mm wide ingot by a direct chill casting process. The ingot was scalped with a scalping machine, removing about 10 mm of material from the surface, then soaked and held for about 5 hours at a soaking temperature shown in Table 1. When the temperature had fallen to 400° C., the ingot was rolled with a hot rolling mill to a thickness of 2.7 mm. In addition, heat treatment was carried out at 500° C. in a continuous annealing furnace, and then each plate was rolled with a cold rolling mill to a thickness of 0.33 mm. The aluminum plate embossing roll manufactured in the above processes was used to carry out cold rolling to obtain aluminum plates 1 to 8 having a thickness of 0.3 mm, a width of 1060 mm and an average roughness Rₐ of 0.6 μm.

An aluminum plate 9 was obtained by repeating the method used for the aluminum plate 1 except that cold rolling was carried out without using the aluminum plate embossing roll manufactured in the above processes to obtain an average roughness R₈ of 0.2 μm.

TABLE 1

| | | | | | | | | | | | | | | Amount | |
|---|---|---|---|---|---|---|---|---|---|---|---|---|---|---|---|
| | | | | | | | | | | | | | Soak- | of Fe | Surface |
| | Component | | | | | | | | | | | | ing | in | rough- |
| Alumi- | | | | | | | | | | Si | Ti | Mg | temper- | solid | ness |
| num | Fe | Cu | In | Ga | V | Pb | Zn | Ni | Cr | (wt | (wt | (wt | ature | solution | Ra |
| plate | (wt %) | (ppm) | (ppm) | (ppm) | (ppm) | (ppm) | (ppm) | (ppm) | (ppm) | %) | %) | %) | (° C.) | (ppm) | (μm) |
| 1 | 0.30 | 15 | 5 | 50 | 50 | 10 | 10 | 10 | 10 | 0.08 | 0.180 | 0.001 | 480 | 25 | 0.6 |
| 2 | 0.39 | 30 | 10 | 60 | 70 | 20 | 5 | 10 | 5 | 0.09 | 0.200 | 0.001 | 500 | 45 | 0.6 |
| 3 | 0.06 | 10 | 0 | 50 | 50 | 5 | 10 | 5 | 5 | 0.06 | 0.001 | 0.000 | 450 | 15 | 0.6 |
| 4 | 0.29 | 250 | 10 | 70 | 60 | 10 | 5 | 5 | 5 | 0.08 | 0.019 | 0.002 | 480 | 25 | 0.6 |
| 5 | 0.30 | 40 | 10 | 60 | 60 | 10 | 10 | 10 | 10 | 0.08 | 0.020 | 0.001 | 480 | 25 | 0.6 |
| 6 | 0.30 | 150 | 5 | 70 | 60 | 10 | 5 | 5 | 10 | 0.07 | 0.025 | 0.001 | 480 | 25 | 0.6 |
| 7 | 0.30 | 15 | 5 | 50 | 50 | 10 | 10 | 10 | 10 | 0.08 | 0.180 | 0.001 | 400 | 10 | 0.6 |
| 8 | 0.30 | 40 | 5 | 5 | 5 | 5 | 5 | 5 | 5 | 0.08 | 0.150 | 0.001 | 480 | 25 | 0.6 |
| 9 | 0.30 | 15 | 5 | 50 | 50 | 10 | 10 | 10 | 10 | 0.08 | 0.180 | 0.001 | 480 | 25 | 0.2 |

3. Fabrication of Lithographic Printing Plate Support

### Examples 1 to 7 and 10, and Comparative Examples 1 to 7

The aluminum plates obtained in the above-processes were subjected to surface treatments described below to obtain the lithographic printing plate supports in Examples 1 to 10 and Comparative Examples 1 to 7 as shown in Table 2.

<Surface Treatment>

The aluminum plates were successively subjected to the following surface treatments (a) to (g).

(a) Etching in Aqueous Alkali Solution (First Etching Treatment)

Etching was carried out by spraying the aluminum plates with an aqueous solution having a sodium hydroxide concentration of 370 g/L, an aluminum ion concentration of 100 g/L and a temperature of 60° C. from a spray line. The amount of material removed by etching from the surface of each aluminum plate to be subsequently subjected to electrochemical graining treatment was as shown in Table 2.

The solution was removed from the plates with nip rollers. Rinsing treatment was then carried out for 5 seconds using fanned-out sprays of water from spray tips mounted on spray lines, and the rinse water was removed from the plates with nip rollers.

(b) Desmutting in Aqueous Acidic Solution (First Desmutting Treatment)

Desmutting was carried out for 5 seconds by spraying the aluminum plates with an aqueous solution having a sulfuric acid concentration of 170 g/L, an aluminum ion concentration of 5 g/L and a temperature of 50° C. from a spray line. Wastewater from the subsequently described anodizing treatment step (f) was used here as the aqueous sulfuric acid solution.

The solution was removed from the plates with nip rollers. Rinsing treatment was then carried out for 5 seconds using fanned-out sprays of water from spray tips mounted on spray lines, and the rinse water was removed from the plates with nip rollers.

(c) Electrochemical Graining with Alternating Current in Aqueous Acidic Solution (Electrochemical Graining Treatment)

Electrochemical graining was carried out with respect to the aluminum plates subjected to the treatment (b) by using aqueous solutions having hydrochloric acid concentrations, sulfuric acid concentrations and nitric acid concentrations shown in Table 2, and having an aluminum ion concentration of 5 g/L (temperature: 35° C.) as the electrolyte solutions, controlling the current through inverter control using an IGBT device, and utilizing a power supply capable of generating an alternating current of any waveform.

The amount of electricity for the alternating current used was as shown in Table 2. The amount of electricity refers to the total amount of electricity when the aluminum plate serves as an anode.

For the concentration control of the electrolyte solutions, a method was used in which hydrochloric acid, nitric acid and water were added in amounts proportional to the amount of applied electricity according to the predetermined data table, multi-component concentration measurement was carried out by the capillary electrophoretic analysis and the amounts of hydrochloric acid, nitric acid and water to be added were corrected based on the obtained results.

At the end of the treatment, the solutions were removed from the plates with nip rollers. Rinsing treatment was then carried out for 5 seconds using fanned-out sprays of water from spray tips mounted on spray lines, and the rinse water was removed from the plates with nip rollers.

(d) Etching in Aqueous Alkali Solution (Second Etching Treatment)

Etching was carried out by spraying the aluminum plates with an aqueous solution having a sodium hydroxide concentration of 50 g/L, an aluminum ion concentration of 5 g/L and a temperature of 35° C. from a spray line. The amount of materials removed by etching from the surfaces of the aluminum plates subjected to the electrochemical graining treatment was 0.2 g/m².

The solution was removed from the plates with nip rollers. Rinsing treatment was then carried out for 5 seconds using fanned-out sprays of water from spray tips mounted on spray lines, and the rinse water was removed from the plates with nip rollers.

(e) Desmutting in Aqueous Acidic Solution (Second Desmutting Treatment)

Desmutting was carried out for 5 seconds by spraying the aluminum plates with an aqueous solution having a sulfuric acid concentration of 170 g/L, an aluminum ion concentration of 5 g/L and a temperature of 50° C. from a spray line. Wastewater from the subsequently described anodizing treatment step (f) was used here as the aqueous sulfuric acid solution.

The solution was removed from the plates with nip rollers. Rinsing treatment was then carried out for 5 seconds using fanned-out sprays of water from spray tips mounted on spray lines, and the rinse water was removed from the plates with nip rollers.

(f) Anodizing Treatment

The electrolyte solution used was prepared by dissolving aluminum sulfate in a 170 g/L aqueous sulfuric acid solution to an aluminum ion concentration of 5 g/L, and had a temperature of 50° C. Anodizing treatment was carried out in such a way that the average current density during the anodic reaction of the aluminum plate to be treated was 15 A/dm². The final weight of the anodized layer was 2.5 g/m².

The solution was removed from the plates with nip rollers. Rinsing treatment was then carried out for 5 seconds using fanned-out sprays of water from spray tips mounted on spray lines, and the rinse water was removed from the plates with nip rollers.

(g) Hydrophilizing Treatment

Hydrophilizing treatment was carried out by immersing the aluminum plates in a 1 wt % solution of sodium silicate in water (solution temperature: 20° C.) for 10 seconds. The amount of silicon on the surface of each aluminum plate, as measured by a fluorescent x-ray analyzer, was 3.5 mg/m².

The solution was removed from the plates with an air knife. Rinsing treatment was then carried out for 5 seconds using fanned-out sprays of water from spray tips mounted on spray lines, and the rinse water was removed from the plates with nip rollers. After that, the aluminum plates were dried by blowing 90° C. air thereon for 10 seconds, thereby giving the lithographic printing plate supports.

4. Surface Examination of Lithographic Printing Plate Support

The surface profile of the lithographic printing plate supports obtained in Examples 1 to 10 was examined under a scanning electron microscope (JSM-5500 manufactured by JEOL, Ltd.; the same applies below) at a magnification of 50,000×, whereupon fine recesses with a diameter of 0.1- to 0.5 μm were found to have uniformly and densely been formed on the surface of each support. In addition, it was found upon the examination under the scanning electron microscope at a magnification of 2,000× that recesses with a diameter of 2 to 10 μm had been formed on the surface of each lithographic printing plate support. The fine recesses with a diameter of 0.1 to 0.5 μm were superimposed on the recesses with a diameter of 1 to 5 μm. The recesses with a diameter of 2 to 10 μm were generally separate from one another and had uniformity.

On the other hand, the surface profile of the lithographic printing plate supports obtained in Comparative Examples 1 to 7 was also examined in the same manner, and fine recesses with a diameter of 0.1 to 0.5 μm and recesses with a diameter of 2 to 10 μm were found to have been formed on the surface of each support. The recesses with a diameter of 2 to 10 μm, however, were overlapping on their edges more frequently than in the above Examples and lacked uniformity.

5. Fabrication of Presensitized Plate

Presensitized plates for lithographic printing were fabricated by providing a thermal positive-type image recording layer in the manner described below on the respective lithographic printing plate supports obtained as above. Before providing the image recording layer, an undercoat was formed on the support as follows.

An undercoating solution of the composition indicated below was applied onto the lithographic printing plate supports and dried at 80° C. for 15 seconds, thereby forming an undercoat layer. The weight of the undercoat layer after drying was 15 mg/m².

Composition of Undercoating Solution

| | |
|---|---|
| Polymeric compound of the following formula | 0.3 g |
| 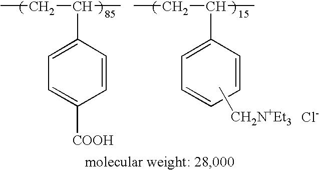 | |
| Methanol | 100 g |
| Water | 1 g |

Next, a heat-sensitive layer-forming coating solution of the following composition was prepared and applied onto the undercoated lithographic printing plate supports to a coating weight (heat-sensitive layer weight) after drying of 1.8 g/m². As a result of subsequent drying, a heat-sensitive layer (thermal positive-type image recording layer) was formed and presensitized plates were thus obtained.

Composition of Heat-Sensitive Layer-
Forming Coating Solution

| | |
|---|---|
| Novolak resin (m-cresol/p-cresol = 60/40; weight-average | 0.90 g |
| molecular weight, 7,000; unreacted cresol content, 0.5 wt %) | |
| Ethyl methacrylate/isobutyl methacrylate/methacrylic acid | 0.10 g |
| copolymer (molar ratio, 35/35/30) | |
| Cyanine dye A of the following formula | 0.1 g |
| 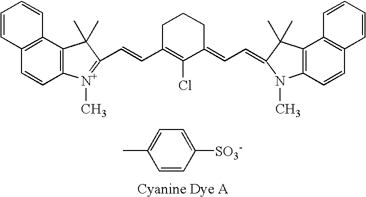 | |
| Tetrahydrophthalic anhydride | 0.05 g |
| p-Toluenesulfonic acid | 0.002 g |
| Ethyl violet in which counterion was 6-hydroxy-β- | 0.02 g |
| naphthalenesulfonic acid | |
| Fluorochemical surfactant (Megaface F-780F, product of | 0.0045 g |
| Dainippon Ink and Chemicals, Inc.; 30 wt % solids) | (as solids) |
| Fluorochemical surfactant (Megaface F-781F, product of | 0.035 g |
| Dainippon Ink and Chemicals, Inc.; 100 wt % solids) | |
| Methyl ethyl ketone | 12 g |

6. Evaluation of Presensitized Plate

The resulting presensitized plates were used to manufacture lithographic printing plates, which were then evaluated for their press life, scumming resistance, resistance to piling and resistance to burning. Evaluation methods were as follows.

(1) Press Life

Trendsetter manufactured by Creo was used to form an image on each presensitized plate at a drum rotation speed of 150 rpm and a beam intensity of 10 W.

The presensitized plates were then developed for 20 seconds with PS Processor 940H manufactured by Fuji Photo Film Co., Ltd. that was charged with an alkaline developer of the following composition, thereby obtaining lithographic printing plates. The developer was maintained at 30° C. The presensitized plates were all excellent in sensitivity.

Composition of Alkaline Developer

| | | |
|---|---|---|
| D-sorbitol | 2.5 | wt % |
| Sodium hydroxide | 0.85 | wt % |
| Polyethylene glycol lauryl ether | 0.5 | wt % |
| (weight-average molecular weight: 1,000) | | |
| Water | 96.15 | wt % |

Printing was carried out with the obtained lithographic printing plates on a Lithrone printing press manufactured by Komori Corporation using DIC-VALUES black ink, a product of Dainippon Ink and Chemicals, Inc. The press life of each printing plate was evaluated by the number of sheets that were printed until the density of solid images began to decline on visual inspection.

Results are shown in Table 3. Meanings of the letters in the table are as follows.
A: The number was 50,000 or more.
B: The number was 30,000 or more but less than 40,000.
C: The number was less than 30,000.
   (2) Scumming Resistance

With the lithographic printing plates obtained in the same manner as in the evaluation of press life as described in (1) above, printing was carried out on a Mitsubishi DAIYA F2 printing press (manufactured by Mitsubishi Heavy Industries, Ltd.) using DIC-GEOS (s) magenta ink. The scumming resistance of each printing plate was evaluated by visually inspecting the blanket for stains after ten thousand printed sheets had been made.

Results are shown in Table 3. Meanings of the letters in the table are as follows.
A: The blanket had almost no stains.
B: The blanket had a few stains.
C: The blanket was certainly stained and the printed sheets were evidently stained.
   (3) Resistance to Piling

The resistance to piling was evaluated by carrying out the following steps (a) to (c):

(a) Fabrication of Lithographic Printing Plate using AM (Amplitude Modulating) Screening Technique

Trendsetter manufactured by Creo was used to form wholly black, square-shaped images each having a width of 10 mm and a length of 5 mm on each of the obtained presensitized plates at a drum rotation speed of 150 rpm and a beam intensity of 10 W according to the AM screening technique.

Thereafter, the presensitized plates were developed as in (1) above to obtain lithographic printing plates. The presensitized plates were all excellent in sensitivity.

(b) Fabrication of Lithographic Printing Plate using FM (Frequency Modulating) Screening Technique

Trendsetter (manufactured by Creo) on which Staccato 20 was mounted was used to form dot images at a halftone dot area ratio of 5% on each of the obtained presensitized plates at a drum rotation speed of 150 rpm and a beam intensity of 10 W according to the FM screening technique. Then, the presensitized plates were developed as in (1) above to obtain lithographic printing plates.

This method was repeated to form dot images on each of the presensitized plates at halftone dot area ratios of 25% and 50%, respectively, thereby obtaining lithographic printing plates.

The presensitized plates were all excellent in sensitivity.

(c) Printing of Each Lithographic Printing Plate and Inspection for Occurrence of Piling

The lithographic printing plates obtained in (a) and (b) above were used to carry out printing on coated paper in a Mitsubishi DAIYA F2 printing press (manufactured by Mitsubishi Heavy Industries, Ltd.) while supplying black ink and cyan ink to a first and a second blanket cylinder, respectively. The first and second blanket cylinders were visually inspected for occurrence of piling after twenty thousand printed sheets had been made.

Results are shown in Table 3. Meanings of the letters in the table are as follows.
A: No piling occurred.
B: Piling occurred.
C: Piling frequently occurred.
   (4) Resistance to Burning

The lithographic printing plates obtained in the same manner as in the evaluation of press life as described in (1) above were subjected to heat treatment at 30° C. for 7 minutes using a burning processor manufactured by Fuji Photo Film Co., Ltd. The lithographic printing plates having undergone heat treatment were judged according to whether or not softening occurred.

Results are shown in Table 3. Meanings of the letters in the table are as follows.
A: Softening was not seen.
B: Softening was seen.

As is evident from Table 3, every lithographic printing plate using any of the lithographic printing plate supports obtained by the method of manufacturing a lithographic printing plate support according to the present invention (Examples 1 to 10) had a long press life and an excellent scumming resistance. The press life was particularly excellent and piling occurred very little. The resistance to burning was also excellent.

Particularly, Examples 1 to 9 in which the etching amount in the first etching treatment was not more than 7 g/L were superior in press life and scumming resistance. The press life was particularly excellent and piling was hardly found to occur. Piling was hardly found to occur particularly even in the case where lithographic printing plates were manufactured by the FM screening technique that uses finer dots to form an image.

On the other hand, the case where the amount of Cu in the aluminum plate was too large (Comparative Examples 1 to 3) and the case where the amount of at least one element selected from the group consisting of Ga, V, Zn, In, Ni, Pb and Cr was too small (Comparative Example 5) were inferior in press life and piling was found to occur. Particularly in the case where lithographic printing plates were manufactured using the FM screening technique, piling was found to occur frequently.

The case where the amount of Fe in the solid solution of the aluminum plate was too small (Comparative Example 4) was inferior in press life and resistance to burning.

Further, the case where asperities were not formed on the surface of the aluminum plate using the embossing roll (Comparative Example 6) and the case where the amount of electricity in electrochemical graining treatment was too small (Comparative Example 7) were inferior in press life and scumming resistance and piling was found to occur frequently.

TABLE 2

| | | | Electrochemical graining | | | |
|---|---|---|---|---|---|---|
| | | | Hydro- | | | |
| | | First | chloric | Nitric | Sulfuric | |
| | | etching | acid | acid | acid | Amount |
| | | Etching | concen- | concen- | concen- | of elec- |
| | Aluminum | amount | tration | tration | tration | tricity |
| | plate | (g/m²) | (g/L) | (g/L) | (g/L) | (c/dm²) |
| Ex. 1 | 1 | 3 | 8 | 0 | 0 | 500 |
| Ex. 2 | 1 | 3 | 8 | 0 | 0 | 250 |
| Ex. 3 | 2 | 3 | 8 | 0 | 0 | 250 |
| Ex. 4 | 3 | 3 | 8 | 0 | 0 | 250 |
| Ex. 5 | 1 | 3 | 8 | 0 | 0 | 300 |
| Ex. 6 | 1 | 7 | 8 | 0 | 0 | 250 |
| Ex. 7 | 1 | 7 | 8 | 0 | 0 | 250 |
| Ex. 8 | 1 | 3 | 8 | 6 | 0 | 250 |
| Ex. 9 | 1 | 3 | 8 | 0 | 5 | 250 |
| Ex. 10 | 1 | 8 | 8 | 0 | 0 | 250 |
| CEx. 1 | 4 | 3 | 8 | 0 | 0 | 250 |
| CEx. 2 | 5 | 3 | 8 | 0 | 0 | 250 |
| CEx. 3 | 6 | 3 | 8 | 0 | 0 | 250 |
| CEx. 4 | 7 | 3 | 8 | 0 | 0 | 250 |
| CEx. 5 | 8 | 3 | 8 | 0 | 0 | 250 |
| CEx. 6 | 9 | 3 | 8 | 0 | 0 | 250 |
| CEx. 7 | 1 | 3 | 8 | 0 | 0 | 200 |

TABLE 3

| | | | Resistance to piling | | |
|---|---|---|---|---|---|
| | | Scumming | AM | FM | Resistance |
| | Press life | resistance | screening | screening | to burning |
| Ex. 1 | A | A | A | A | A |
| Ex. 2 | A | A | A | A | A |
| Ex. 3 | A | A | A | A | A |
| Ex. 4 | A | A | A | A | A |
| Ex. 5 | A | A | A | A | A |
| Ex. 6 | A | A | A | A | A |
| Ex. 7 | A | A | A | A | A |
| Ex. 8 | A | A | A | A | A |
| Ex. 9 | A | A | A | A | A |
| Ex. 10 | A | B | A | B | A |
| CEx. 1 | C | A | B | C | A |
| CEx. 2 | B | A | A | C | A |
| CEx. 3 | C | A | B | C | A |
| CEx. 4 | C | A | A | A | B |
| CEx. 5 | B | A | A | C | A |
| CEx. 6 | B | C | B | C | A |
| CEx. 7 | B | C | B | B | A |

What is claimed is:

1. A method of manufacturing a lithographic printing plate support including the step of:
subjecting an aluminum plate at least to electrochemical graining treatment in which alternating current is passed through the aluminum plate in an aqueous solution containing hydrochloric acid so that the total amount of electricity when the aluminum plate serves as an anode is at least 250 C/dm², thereby obtaining a lithographic printing plate support,
wherein the aluminum plate contains not more than 30 ppm of Cu and 10 to 200 ppm of at least one element selected from the group consisting of Ga, V, Zn, In, Ni, Pb and Cr, contains at least 15 ppm of Fe in a form of a solid solution, and has a pattern of recessed and protruded portions formed on a surface thereof.

2. The method of manufacturing a lithographic printing plate support according to claim 1, in which the aluminum plate contains 0.05 to 0.4 wt % of Fe.

3. The method of manufacturing a lithographic printing plate support according to claim 1 or 2, in which the aluminum plate is etched using an alkaline aqueous solution prior to the electrochemical graining treatment so that the amount of aluminum dissolved is not more than 7 g/m².

4. The method of manufacturing a lithographic printing plate support according to claim 1 or 2, in which the pattern of recessed and protruded portions on the surface of the aluminum plate is formed by rolling using a roll having a pattern of recessed and protruded portions formed on a surface thereof.

5. The method of manufacturing a lithographic printing plate support according to claim 1 or 2, in which the aluminum plate satisfies one or more selected from the group consisting of a Si content of 0.03 to 0.1 wt %, a Ti content of 0.001 to 0.03 wt % and a Mg content of 0.001 to 0.5 wt %.

6. The method of manufacturing a lithographic printing plate support according to claim 1 or 2, in which the aqueous solution containing hydrochloric acid further contains nitric acid or sulfuric acid.
